(19) United States
(12) Patent Application Publication
(10) Pub. No.: US 2017/0010681 A1
(43) Pub. Date: Jan. 12, 2017

(54) DATA EXECUTION DEVICE

(71) Applicant: Ju Hyup LEE, Suwon-si (KR)

(72) Inventor: Ju Hyup LEE, Suwon-si (KR)

(21) Appl. No.: 15/101,514

(22) PCT Filed: Dec. 17, 2014
(86) PCT No.: PCT/KR2014/012486

§ 371 Date: Jun. 3, 2016

(30) Foreign Application Priority Data
Dec. 18, 2013 (KR) 10-2013-0158805

(51) Int. Cl. G06F 3/02; G06F 3/023; H03K 17/96; G06F 3/0489

(52) U.S. Cl. CPC G06F 3/0219; G06F 3/0489; G06F 3/0236; H03K 17/96

(57) ABSTRACT

A data execution device includes an input module including a single selection unit having three different selection locations at which selection is performed via a finger, i.e., a selection means, and a sensor unit having sensors generating signals in response to the selection; wherein the input module is provided to include three contact locations under the selection unit, located under the selection locations, and at least three sensors of the sensor unit spaced apart from the contact locations, respectively, by a predetermined distance, the selection locations are located within a range corresponding to the fingerprint region of a single thumb, and a separation distance formed under the center of the selection unit is configured to be shorter than a separation distance formed under each of the one side and other side of the selection unit.

### TECHNICAL FIELD

The present invention relates to a data execution device. That is, the present invention relates to a data execution device that is provided such that selection via a selection means is performed and data execution assigned to a signal generated by the selection is performed.

### BACKGROUND ART

Recently, the demand of users for an execution device that enables data input or data control to be executed in an electronic device or the like has been further diversified,

Providers who supply such execution devices have increased the degree of completion of the execution devices in response to the demands of users in the form of upgrades of the usability, convenience, industrial application and the like of the execution devices, and have competitively developed various types of electronic devices or data execution devices for specializing these electronic devices.

As an example, the “Character Input Device for Display Device” of Korean Patent. No. 2010-0081202 (published on Jul. 14, 2010) was disclosed.

The character input device for a display device according to the invention includes: a remote controller configured to have a plurality of direction keys, and to transmit signals corresponding to the direction keys; and a display device configured to display characters on a screen with one or more characters mapped to each of the direction keys, and to sequentially select and input characters mapped to a direction key when the direction key is pressed and thus a signal corresponding to the direction key is input from the remote controller.

In the invention, the characters are mapped to the direction keys using different arrangement methods; the arrangement method may be selected as desired; and the arrangement methods are divided into a QWERTY method for performing arrangement according to a keyboard arrangement, an alphabetical sequence method for performing arrangement according to the sequence of characters, and a frequency method for performing arrangement according to the frequencies of character selection.

The above-described invention has a problem in that a user can execute data input only if the character input device undergoes a preset selection procedure including at least two steps (a direction key input step of displaying the characters on a screen and a space key input step of sequentially selecting and inputting the characters mapped to the direction key).

That is, the character input device has a problem in that it is not easy to rapidly execute various data inputs because data input, is executed in such a manner that the characters mapped to the direction key are sequentially selected and executed in the selection.

Furthermore, problems arise in that the concentration of a user is required for two or more repetitive different independent selection or successive selection operation in the data input and the fatigue of the user is increased in the selection.

As another, example, the “Data Input Device and Data Input Method” of Korean Patent No. 2009-0105864 (published on Oct. 7, 2009) was disclosed.

In the data, input device and data input method of the patented invention, a detection unit provided in a predetermined detection region formed on one side of the case of a terminal for an electronic device is configured to include a control, unit, configured to detect horizontal pressing of a finger placed at a reference location within the detection region in a predetermined radial direction and generate a first direction input signal; detect vertical pressing inclined in a predetermined direction in the state in which a finger has been placed at the reference location and generate a second direction input signal; and determine a horizontal pressing direction or vertical pressing location of the finger from the first collection input signal and the second direction input, signal, extract data assigned to the corresponding radial direction and pressing location from a memory unit, and input the data.

That is, in the invention, the user can execute data input in such a manner as to successively use the horizontal pressing, the vertical pressing, or the horizontal pressing and the vertical pressing in a mixed fashion or to repetitively perform the horizontal pressing, the vertical pressing, or the horizontal pressing and the vertical pressing.

The above-described invention has a problem in that a user must separately learn or become well-acquainted with an independent input keyboard arrangement formed radially on the basis of the predetermined location of the data input device.

Furthermore, a problem arises in that the stress of the user increases in data input through the selection because high concentration of the user is required to prevent an input typing error and increase input accuracy in an input operation of selecting one or more of the reference location and a plurality of indication locations.

In order to overcome the above-described problems, there is a demand for the invention of a data execution device, in which a compact structure input unit configured to enable selection via a selection means is performed within a range corresponding to the fingerprint of a single thumb is provided, a few selection locations at which the selection is performed in die input unit can be intuitively recognized by a single finger, and the different independent selections or successive selections of the selection locations can be naturally performed by the recognition without requiring separate learning, thereby enabling data execution adapted to perform one or more of data input and data control via the selection to be easily and rapidly performed independently or successively.

### DISCLOSURE

### Technical Problem

The present invention is intended to overcome the above-described problems of the conventional art, and an object of the present invention is to provide a data execution device, in which an input unit having a compact structure that enables selection via a selection means to be performed within a range corresponding to the fingerprint of a single thumb, a few selection locations at which the selection is performed in the input unit can be intuitively recognized by a single finger, and different independent selections or successive selections of the selection locations can be naturally performed by the recognition without requiring separate learning, thereby enabling data execution adapted to perform one or more of data input or data control via the selection to be easily and rapidly performed independently or successively.

### Technical Solution

As a technical solution to the accomplishment of the object of the present invention, according to a first aspect of the present invention, there is provided a data execution device, in which selection via a selection means is performed in a selection unit and data execution assigned to a signal generated by the selection is performed, wherein; at least one input module, including a selection unit configured to enable a selection via a finger, which is one of the selection means, to be performed and configured to have a predetermined width and length, and a sensor unit configured to have sensors generating signals in response to the selection, is included; in the input module, the selection unit includes a single selection unit; a reference location and side locations corresponding to selection locations at which the selection is performed in the selection unit are provided to be located within a range corresponding to a fingerprint region on the basis of a fingerprint in a distal end portion of a single thumb, the reference location and the side locations are located to be spaced apart from each other by a predetermined distance along a single lateral axis within the selection unit, the reference location is located at one point at a center of the selection unit, and the side locations include a first side location located on one side of the selection unit and a second side location located on a remaining side of the selection unit; contact locations that correspond to the selection of the reference location and the side locations and come into contact with sensors of the sensor unit are located at predetermined locations under the selection unit; the contact locations include a reference contact location located at a predetermined location under the reference location, a first contact location located at a predetermined location under the first side location, and a second, contact location located at a predetermined location under the second side location; the sensor unit is provided at a location spaced apart from a bottom of the selection unit by a predetermined distance; the sensors of the sensor unit include a reference sensor located in the sensor unit under the reference contact location and configured to be brought into contest with the reference contact location by the selection, a first sensor located in the sensor unit under the first contact location and configured to be brought into contact with the first contact location by the selection, and a second sensor located in the sensor unit under the second contact location and configured to be brought into contact with the second contact location by the selection; the input module is provided to have predetermined separation distances across which a contact via the selection and a return from the contact location to an original location are made, in the input module, the separation distances include: a reference interval corresponding to a space along an axis between a predetermined location under the selection unit and the reference sensor of the sensor unit that are spaced apart from each other by a predetermined distance in this axis vertically passing through the reference location; a first interval corresponding to a space along an axis between a predetermined location under the selection unit and the first sensor of the sensor unit that are located to be spaced apart from each other by a predetermined distance in this axis vertically passing through the first side location; and a second interval corresponding to a space along, the axis between a predetermined location under the selection unit and the second sensor of the sensor unit that are located to be spaced apart from each other by a predetermined distance in this axis vertically passing through the second side location; the reference interval is configured to be shorter than each of the first interval and the second interval; in the input module, when the selection of the reference location, the first side location or the second side location is performed, the reference contact location, the first contact location or the second contact location is configured to be moved in a direction of the separation distance, be brought into contact with the sensor of the sensor unit corresponding to the selection, and be returned to its original location; in the input module, when the selection is performed by a single pressing operation centered on the selection unit, including the reference location, on the basis of the selection via the single finger, a predetermined reference signal is generated in the reference sensor brought into contact with the reference contact location by the selection; when the selection is performed by a single pressing operation toward a one or remaining side of the selection unit including the first or second side location, a predetermined side signal is generated in the first sensor brought into contact with the first contact location or in the second sensor brought into contact with the second contact location by the selection; and data execution assigned to the reference signal or the side signal is independently or successively performed

In the input module according to the present invention, one or more members are provided between the selection unit and the sensor, the members include a reference member provided between the reference location and the reference sensor; and in the input module, the separation distance under the reference location is configured to be shorter than the separation distance under each of the first side location and the second side location by the reference member.

In the input module according to the present invention, the members include side members; and the side members include a first member located between the first side location and the first sensor and a second member located between the second side location and the second sensor.

In the input module according to the present invention, the separation distance under the reference location at which the reference member is located is configured to be shorter than the separation distance under each of the first side location at which the first member of the side members is located and the second side location at which the second member is located.

In the input module according to the present invention, the reference member and the side members are provided to be identical or different depending on a predetermined criterion; and the predetermined criterion includes at least one of a size, shape, type and material of the members.

In the input module according to the present invention, on the basis of the selection via the single finger when the selection is performed by a single pressing operation centered on the selection unit including the reference location, a predetermined reference signal is generated in the reference sensor brought into contact with one side of the reference member by the selection; and when the selection is performed by a single pressing operation toward the one or remaining side of the selection unit including the first or second side location, a predetermined side signal is generated in the first sensor brought into contact with one side of the first member or in the second sensor brought into contact with one side of the second member.

In the input module according to the present invention, one side of at least one of the reference member and the side members that are brought into contact with the sensors of the sensor unit during the selection is provided in one or more shapes; or the one side of the at least one is provided to include at least one of a plane portion, a concave portion, a wing portion, a convex portion, a protrusion portion, a variable portion and a protrusion.

In the input module according to the present invention, with regard to sensor actuation pressures that cause predetermined signals to be generated in the sensors of the sensor unit corresponding to the selection of the selection locations in the input module: the sensor actuation pressures include a reference sensor actuation pressure that causes the reference sensor of the sensors to operate and generate the reference signal and side sensor actuation pressures that causes the first sensor or the second sensor of the sensors to operate, and generate the side signals, and the reference sensor actuation pressure and the side sensor actuation pressures are different

With regard to the sensor actuation pressures according the present invention, the reference sensor actuation pressure related to the reference sensor corresponding to the selection of the center of the selection unit is higher than the side sensor actuation pressure related to the first sensor or the second sensor corresponding to the selection of the one or remaining side of the selection unit and the side sensor actuation pressure related to the first sensor and the side sensor actuation pressure related to the second sensor are different.

In the input module according to the present invention, the reference sensor generating the reference signal and the first and second sensors generating the side signals in the input module are provided to be identical or different depending on a predetermined criterion; and the predetermined criterion includes at least one of a size, shape, type and material of the sensors.

The input module according to the present invention includes one or more location balancers having a predetermined width and length; and the location balancers are provided to be located within a space between a bottom of the selection unit and the sensor unit, and are provided between the reference location, spaced apart from the reference location by a predetermined distance in a direction of the side location, and the side locations within the space.

In the input module according to the present invention, the location balancers are provided to be located at predetermined locations spaced apart from the reference location in a direction of the first side location and a direction of the second side location by a predetermined distance with the space; and close contact portions are located at one side end of each of the location balancers in a vertical direction or at one and remaining side ends of each of the location balancers in a vertical direction, and, the close contact portions are formed to be bought into close contact by the selection.

The selection unit according to the present invention is provided to include at least one of an elastic member and a non-elastic member, when the selection is performed toward one or remaining side of the selection unit including the elastic member on the basis of the selection via the single finger performed along a single reference line passing through, the selection unit in a lateral direction, a predetermined portion of the one side or the other side is inclined or bent downward from the reference line within a predetermined angle; and, when the selection is released, the inclined or bent predetermined portion is returned to its original location.

In the input module according to the present invention, with regard to a plurality of reference signals or a plurality of side signals generated when the reference signal or the side signal is successively generated based on a difference in a number of selections or a difference in strength of pressing forte in the selection of the reference location or the side location: on the basis of a predetermined time set value: when a time interval of each signal of the reference signals or the side signals falls within the set time value, the reference signals are processed as a new single reference signal different from each signal of the reference signals or the side signals are processed as a new single side signal different from each signal of the side signals in a predetermined control unit; and, when a time interval of each signal of the reference signals or the side signals exceeds the set time value, the reference signals are processed as respective reference signals successively generated independently or the side signals are processed as side signals successively generated independently in the control unit.

According to a second aspect of the present invention, there is provided a data execution device, in which selection via a selection means is performed in, a selection unit and data execution assigned to a signal generated by the selection is performed, wherein; at least one input module, including a selection unit configured to enable a selection via a finger, which is one of the selection means, to be performed and configured to have a predetermined width and length, and a sensor unit formed under the selection unit and configured to have sensors generating signals in response to the selection, is included; in the input module, the selection unit includes a single selection unit; a reference location and side locations corresponding to selection locations at which the selection is performed in the selection unit are provided to be located within a range corresponding to a fingerprint region on the basis of a fingerprint in a distal end portion of a single thumb, the reference location and the side locations are located to be spaced apart from each other by a predetermined distance along a single lateral axis within the selection unit, the reference location is located at one point at a center of the selection unit, and the side locations include a first side location located on one side of the selection unit and a second side location located on a remaining side of the selection unit; sensors corresponding to the selection of the reference location and the side location are located in the sensor unit; the sensors are configured to include a reference sensor located under the reference location, a first sensor located under the first side location, and a second sensor located under the second side location; a contact unit is provided at a location spaced apart from the sensor unit by a predetermined distance; contact locations each of which corresponds to the selection of the reference location or the side location and is brought into contact with a corresponding sensor of the sensor unit are located at predetermined locations on a top of the contact unit; the contact locations include a reference contact location located at a predetermined location between a bottom of the reference sensor and the top of the contact unit and configured to be brought into contact with the reference sensor by the selection, a first contact location located at a predetermined location between a bottom of the first sensor and the top of the contact unit and configured to is brought into contact with the first sensor by the selection, and a second contact location located at a predetermined location between a bottom of the second sensor and the top of the contact unit and configured to be brought into contact with the second sensor by the selection; the input module is provided to have predetermined separation distances across which a contact via the selection and a return from the contact location to an original location are made, in the input module, the separation distances include: a reference interval corresponding to a space along a single axis between the reference sensor and the contact unit that are located to be spaced apart from each other by a predetermined distance along this single axis vertically passing through the reference location; a first interval corresponding to a space along a single axis the first sensor the contact unit that are located to be spaced apart from each other by a predetermined distance along this single axis vertically passing through the first side location; and a second interval corresponding to a space along a single axis between the second sensor and the contact unit that are located to be spaced apart from each other by a predetermined distance along this single axis vertically passing through the second side location; the reference interval is configured to be shorter than each of the first interval and the second interval; in the input module, when the selection of the reference location, the first side location or the second side location is performed, the reference sensor, the first sensor or the second sensor is moved in a direction of the separation distance, is brought into contact with the contact location of the contact unit corresponding to the selection, and is returned to its original location; in the input module, when the selection is performed by a single pressing operation centered on the selection unit, including the reference location, on the basis of the selection via the single finger, a predetermined reference signal is generated in the reference sensor brought into contact with the reference contact location by the selection; when the selection is performed by a single pressing operation toward a one or remaining side of the selection unit including the first or second side location, a predetermined side signal is generated in the first sensor brought into contact with the first contact location or in the second sensor brought into contact with the second contact location by the selection; and data execution assigned to the reference signal or the side signal is independently or successively performed

In the input module according to the present invention, one or more members are provided between the selection unit and the sensor; the members include a reference member provided between the reference location and the contact unit; and in the input module, the separation distance under the reference location is configured to be shorter than the separation distance under each of the first side location and the second side location by the reference member.

In the input module according to the present invention, the members include side members; and the side members include a first member located between the first sensor and the contact and a second member located between the second sensor and the contact unit,

In the input module according to the present invention, the separation distance under the reference location at which the reference member is located is configured to be shorter than the separation distance under each of the first side location at which the first member of the side members is located and the second side location at which the second member is located.

In the input module according to the present invention, the reference member and the side members are provided to be identical or different depending on a predetermined criterion; and the predetermined criterion includes at least one of a size, shape, type and material of the members.

The input module according to the present invention includes a plurality of input modules; and, the input modules are located to be spaced apart from each other by a predetermined distance in at least one direction.

The input module according to the present invention includes a first input module and a second input module that are spaced apart by a predetermined distance in a vertical direction; in a case based on a single reference line located between the first input module and the second input module in a lateral direction: when the selection via a single finger is performed by a single pressing operation toward a center of the selection unit of the first input module and a center of the selection unit of the second input module on the basis of the reference line, the reference location of the selection unit of the first input module and the reference location of the selection unit of the second input module are selected together by the finger, generation of a single reference signal in the reference sensor brought into contact with the reference contact location of the first input module and generation of another single reference signal in the reference sensor brought into contact with the reference contact location of the second input module are performed together by the selection; and, in, a predetermined control unit, the single reference signal, and the other single reference signal are processed as a third reference signal, which is a new single reference signal, on the basis of predetermined set values of a plurality of signals.

The input module according to the present invention includes a first input module and a second input module that are spaced apart by a predetermined distance in a vertical direction; in a case based on a single reference line located between the first input module and the second input module in a lateral direction: the selection via the single finger is performed by a single pressing operation for one side of the selection unit of the first input module and a remaining side of the selection unit of the second input module, or a remaining side of the selection unit of the first input module and a remaining side of the selection unit of the second input module on the basis of the reference line, the first side location of the selection unit of the first input module and the first side location of the selection unit of the second input module, or, the second side location of the selection unit of the fit input module and the second side location of the selection unit of the second input module are selected together by the finger; generation of a single one side signal in the first sensor brought into contact with the first contact location of the first input module and generation of another single one side signal in the first sensor brought into contact with, the first contact location of the, second input module, or generation of a single other side signal in the second sensor brought into contact with the second contact location of the first input module and generation of another single other side signal in the second sensor brought into contact with the second contact location of the second input module are performed together by the selection; and the single one side signal and the single one side signal, or the single other side signal and the single other side, signal are processed as a third side signal, which is a new single side signal, on the basis of predetermined set values of a plurality of signals in a predetermined control unit

The input module according to the present invention includes a first input module and a second input module that are spaced apart predetermined distance lateral direction; in a case based on a single reference line located between the first input module and the second input module in a vertical direction: when the selection via the single finger is performed by a single pressing operation for a remaining side of the selection unit of the first input module and one side of the selection unit of the second input module, or one side of the selection unit of the first input module and a remaining side of the selection unit of the second input module on the basis of the reference line, the second side location of the selection unit of the first input module and the first side location of the selection unit of the second input module, or the first side location of the selection unit of the first input module and the second side location of the selection unit of the second input module are selected together by the finger; generation of a single other side signal in the second sensor brought into contact with the second contact location of the first input module and generation of a single one side signal in the first sensor brought into contact with the first contact location of the second input module, or generation of a single one side signal in the first sensor brought into contact with the first contact location of the first input module and generation of a single other side signal, in the second sensor brought into contact with the second contact location of the second input module are, performed together by the selection; and the single other side signal and the single one side signal, or the single one side signal and the single other side signal are processed as a third side signal, which is a new single side signal, on the basis of predetermined set values of a plurality of signals in a predetermined control unit.

In the input module according to the present invention, the separation distance under the second side, location of the, first input module and the separation distance under the first side location of the second input module are configured to be different

The input module according to the present invention or the selection unit of the input module is provided according to a predetermined criterion; the predetermined criterion includes at least one of size, shape, member and material; and the shape includes at least one of a plane portion, a concave pardon, a protrusion, a line, a groove, a protrusion portion and an asymmetric shape

The selection unit according to the present invention includes a plurality of selection units; and one and another selection units of the selection units that are spaced apart by a predetermined distance in at least one direction are located to be connected by a predetermined connection frame.

The input module according to the present invention is detachably provided on a body of an execution device that performs the data execution.

Terminals configured to transfer a predetermined signal of the input module or the execution device or a transfer signal of data assigned to the signal are provided at predetermined locations of the input module and the body according to the present invention.

A fastening means configured to fasten the input module and the body to each other are provided at one or more predetermined locations of the input module and the body according to the present invention; and the fastening means includes one or more fastening members of a protrusion, a groove, a slot, a guide, a latch, a hook, a holder, a band and a Velcro fastener.

### Advantageous Effects

According to the present invention, the data execution device is provided to include at least one input module, including a selection unit having three different selection locations at which selections are made by a finger, i.e., one selection means, within a range corresponding to the fingerprint of a single thumb and a sensor unit having, sensors which generate signals in response to the selections. In this case, the input module is provided such that three contact locations under the selection unit, located under the three selection locations, respectively, and the three sensors of the sensor unit, spaced apart from the three contact locations by a Predetermined distance at predetermined intervals, are brought into contact, by the selections and are returned from the contact locations to their original locations. In this case, the three selection locations are located within a range corresponding to a fingerprint in the distal end portion of the single thumb, and a separation distance formed at a predetermined location under the center of the selection unit is configured to be shorter than a separation distance at a predetermined location under each of the one and other sides of the selection unit. By this, the present invention enables the three selection locations (a first side location, a reference location, and a second side location) located at the center and on the one side and the other side to be intuitively recognized by a single finger in a one side-center-other side arrangement. That is, the present invention has the advantage of enabling data execution adapted to perform one or more of data input and data control via the selections to be easily and rapidly performed independently or successively via the above-described features.

Furthermore, in the present invention, the independent or successive selections of the recognized selection locations can be naturally made in the selection unit by the minute movement of the single finger in the state in which a user does not carefully observe the selection unit or the selection locations of the selection unit. That is, the present invention has the advantages of suppressing the occurrence of typing errors in different independent selections or successive selections made two or more limes, and preventing the accumulation of fatigue or reducing the occurrence of stress attributable to the selections.

Furthermore, the present invention enables the different independent selections or successive selections of the selection locations to be naturally performed by the recognition without requiring separate learning. That is, the present invention has an advantage in that a user can naturally make selections of one or more of the selection locations (the first side location, the reference location, and the second side, location) using familiar selection operations of the single finger without requiring separate learning even in the state in which the user carries, grips or wears the device of the present invention, transfers or moves.

Furthermore, the selection unit of the present invention includes a compact-structure single selection unit having a predetermined width and length within a range corresponding to the fingerprint of a single thumb. Accordingly, the present invention has the advantage of being easily applied to various types of electronic devices including a wearable device, a variable device, an Internet of Things (IoT) device, a composite device, etc., the advantage of being easily configured in the form of a detachable or portable accessory in each of the electronic devices, and the advantage of providing the opportunity of configuring more various devices and an more improved user environment for data execution to a user in the field of data execution devices.

### DESCRIPTION OF DRAWINGS

FIG. 1 is a schematic diagram showing the configuration of an embodiment of a data execution device according to the present invention;

FIG. 2 is a diagram illustrating an example in which, in data execution using the data execution device according to the embodiment of the present invention, data execution is performed by the selection of a single finger for the selection unit of the data execution device;

FIG. 3 is a diagram illustrating examples of the schematic configuration of the input module according to an embodiment of the present invention and the configuration of a separation distance formed in the input module;

FIG. 4 is a diagram illustrating examples of various configurations of separation distances according to embodiments of the present invention different from that of FIG. 3;

FIG. 5 a diagram illustrating an example of the configuration of a member provided at a predetermined location between a contact location and a sensor in an input module according to an embodiment of the present invention;

FIG. 6 is a diagram illustrating examples of various configurations of an input module according to an embodiment of the present invention;

FIGS. 7 and 8 are diagrams illustrating examples of various configurations of location balancers provided in input modules according to embodiments of the present invention;

FIGS. 9 and 10 are diagrams illustrating examples of data execution based on the configuration of a selection unit or the configuration of a selection unit according to an embodiment of the present invention;

FIG. 11 is a diagram illustrating examples of selection performed in an input module according to an embodiment of the present invention, the generation of a signal via the selection, and data execution assigned to the signal;

FIG. 12 is a diagram illustrating an example of the configuration of a plurality of input modules according to an embodiment of the present invention, selection performed in the input modules, the generation of a signal via the selection or data execution assigned to the signal;

FIG. 13 is a diagram illustrating an example of a signal generated in a sensor of a sensor unit according to the embodiment of the present invention shown in FIG. 11 or 12;

FIG. 14 is a diagram illustrating an example of a signal generated in a sensor of a sensor unit according to an embodiment of the present invention different form FIG. 13;

FIG. 15 is a diagram illustrating examples of the configuration of data, assigned to a signal according to the present invention shown in FIG. 13 or 14, or various embodiments of data execution;

FIG. 16 is a diagram illustrating examples of various configurations of an input module according to an embodiment of the present invention or a selection unit provided in the input module;

FIG. 17 is a diagram illustrating examples of various configurations of a plurality of input modules, or the selection units of the input modules according to embodiments of the, present invention; and.

FIGS. 18 and 19 are diagrams illustrating examples of the configuration and application of a data execution device or an input module according to an embodiment of the present invention.

### BEST MODE

As a best mode for the practice of the invention, there is provided a data execution device 1, in which selection via a selection means is performed in a selection unit and data execution assigned to a signal generated by the selection is performed, wherein:

at least one input module 50, including a selection unit 100 configured to enable a selection via a finger, which is one of the selection means, to be performed and to have a predetermined width and length, and a sensor unit 300 configured to have sensors generating signals in response to the selection, is, included;

in the, input module, the selection unit includes a single selection unit;

a reference location and side locations corresponding to selection locations at which the selection is performed in the selection unit are provided to be located within a range corresponding to a fingerprint region, on the basis of a fingerprint, in a distal end portion of a single thumb, the reference location and the side locations are located to be spaced apart from each other by a predetermined distance along a single lateral axis within the selection unit, the reference location is located at one point at a center of the selection unit, and the side locations include a first side location located on one side of the selection unit and a second side location located on a remaining side of the selection unit;

contact locations that correspond to the selection of the reference location and the side locations and come into contact with sensors of the sensor unit are located at predetermined locations under the selection unit;

the contact locations include a reference contact location located at a predetermined location under the reference location, a first contact location located at a predetermined location under the first side location, and a second contact location located at a predetermined location under the second side location;

the sensor unit is provided at a location spaced apart from a bottom of the selection unit by a predetermined distance;

the sensors of the sensor unit include a reference sensor located in the sensor unit under the reference contact location and configured to be brought into contact with the reference contact location by the selection, a first sensor located in the sensor unit under the first contact location and configured to be brought into contact with the first contact location by the selection, and a second sensor located in the sensor unit under the second contact location and configured to be brought into contact with the second contact location by the selection;

the input module is provided to have predetermined separation distances across which a contact via the selection and a return from the contact location to an original location are made,

in the input module, the separation distances include: a reference interval corresponding to a space along an axis between a predetermined location under the selection unit and the reference sensor of the sensor unit that are spaced apart from each other by a predetermined distance in this axis vertically passing through the reference location; a first interval corresponding to a space along an axis between a predetermined location under the selection unit and the, first sensor of the sensor unit that are located to be spaced apart from each other by a predetermined distance in this axis vertically passing through the first side location; and a second interval corresponding to a space along the axis between a predetermined location under the selection unit and the second sensor of the sensor unit that are located to be spaced apart from each other by a predetermined distance in this axis vertically passing through the second side location;

the reference interval is configured to be shorter than each of the first interval and the second interval;

in the input module, when the selection of the reference location, the first side location or the second side location is performed, the reference contact location, the first contact location or the second contact location is configured to be moved in a direction of the separation distance, be brought into contact with the sensor of the sensor unit corresponding to the selection, and be returned to its original location;

in the input module, when the selection is performed by a single pressing operation centered on the selection unit, including the reference location, on:the basis of the selection via the single finger, a predetermined reference signal is generated in the reference sensor brought into contact with the reference contact location by the selection;

when the selection is performed by a single pressing operation toward a one, or remaining side of the selection unit including the first or second side location, a predetermined side signal is generated in the first sensor brought into contact with the first contact location or in the second sensor brought into contact with the second contact location by the selection; and

data execution assigned to the reference signal or the side signal is independently or successively performed.

### MODE FOR INVENTION

Embodiments of a data execution device 1 according to the present invention will be described in detail below with reference to the accompanying drawings.

The meanings of terms used herein are described first.

In the present invention, a selection location refers to a predetermined location at which selection via a selection means is performed. The predetermined location may be a single point. Alternatively, the predetermined location may refer to a predetermined portion including the single point in an embodiment. The reference location and the side locations of a selection unit'according to the present invention correspond to such selection locations.

In the present invention, a selection refers to a selection of a selection location via a selection means or a selection operation for a selection location via a selection means. According to an embodiment of the present invention, the selection may include the force of the selection means that is applied to the selection location.

In the present invention, a selection operation refers to the act of selecting the selection location via a selection means or the movement of a selection means that enables the selection to be performed. The selection operation includes pressing, clicking, tilting, rolling, etc.

In the present invention, a selection means includes a finger, an auxiliary means, etc. Although a thumb of a user is suitable for the selection means, a finger, one of the selection means, is not limited to the thumb. The auxiliary means includes a finger glove, a thimble, a finger glove- or thimble-shaped auxiliary device, etc.

In the present invention, “be located” or “locate” includes the meaning “be present at a designated location” or “be made to be present at a designated location,” and may include the meaning “be formed” based on the configuration of the invention.

In the present invention, one side and other side refer to locations that are spaced apart from a predetermined reference, including a reference location or a virtual line, in a predetermined direction and that face each other. The one side and the other side include the left side, right side, upper side (front side), and lower side (rear side) of the reference, etc. That is, the one side or the other side may be set to one of the locations. For example, the one side may be set to a left side according to the predetermined criterion, or may be set to a right side according to an embodiment of the present invention.

In the present invention, data execution refers to causing data, assigned to a signal generated by the selection of the selection location via a selection means in a sensor unit, to be output to an electronic device. Furthermore, the data execution may refer to causing data, assigned to a signal generated in a sensor unit, to be output to and executed in, an electronic device.

A signal according to the present invention includes an electrical signal based on an event. The event includes the above-described selection or selection operation. The signal or electrical signal may be composed of an analog signal, a digital signal, a composite signal, etc. Furthermore, the signal or electrical signal may be configured to be transferred via a predetermined terminal. Alternatively, a transfer signal corresponding to the signal or electrical signal may be configured to be transferred via the terminal.

An electronic device according to the present invention collectively refers to all electric and electronic products that are manufactured to, use or adaptively use electronic technology and apply it to actual life. The electronic device includes a computer device, a sound device, an image device, an information device, a communication device, an information and communication device, a game device, a wired device, a wireless device, a wearable device, a video device, a variable device, an IoT device, a composite device, etc. Furthermore, the configuration of the electronic device may include various types of terminals, peripheral devices, devices, interface units, etc.

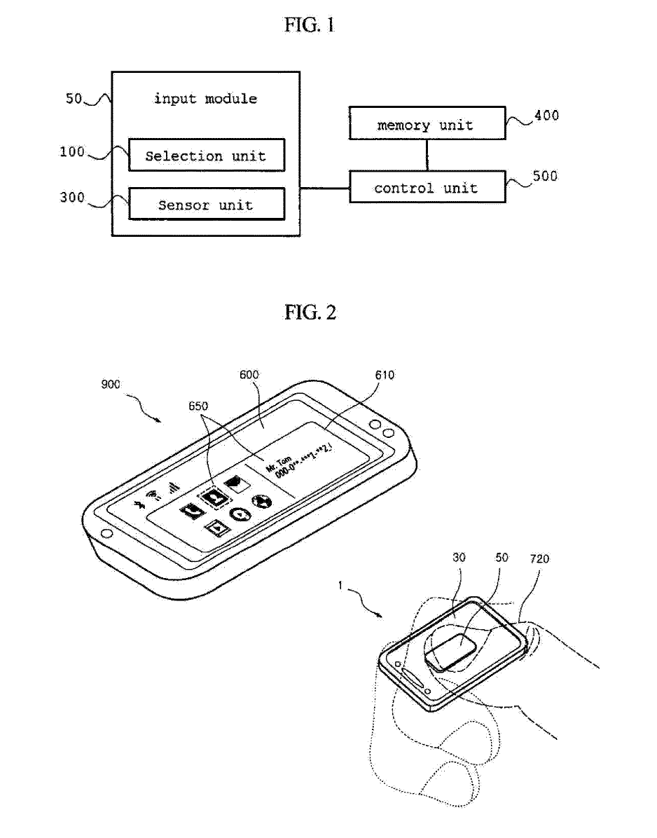

FIG. 1 is a schematic diagram showing the configuration of an embodiment of a data execution device according to the present invention.

As shown in FIG. 1, the data execution device includes at least one input module 50, a memory unit 400, and a control unit 500.

The input module is configured such that selection is performed by a finger 720, i.e., a selection means, and includes a single selection unit 100 having a predetermined with and length and a sensor unit 300 having a sensor that generates a signal in response to the selection.

Data assigned to a predetermined signal is, stored, in the memory unit. The data may be divided into predetermined unit menus, and may be stored the memory unit. Furthermore, the data may be divided into a few data sets, and may be stored in the memory unit.

The control unit receives and determines a signal generated by the sensor unit, extracts data assigned to the determined signal from the memory unit, and processes the data

In greater detail, the following description is given via various embodiments.

FIG. 2 is a diagram illustrating an example in which in data execution using the data execution device 1 according to the embodiment of the present invention, the data execution is performed by, the selection of a single finger 720 for the selection unit 100 of the data execution device.

As shown in FIG. 2 the data execution device may be configured to be connected to an electronic device 900 having a display unit 600 or display portion 610 in a wired or wireless manner.

That is the present invention has a structure in which selection locations are intuitively recognized by the finger placed on the selection unit in the state in which the single finger 720 has been located in a region centered on the selection unit or in the state in which a user does not carefully observe the selection unit or the selection locations of the selection unit.

That is the selection unit has the features of enabling independent or successive selections of the recognized selection location to be naturally performed by the minute movement of the single finger 720, suppressing the occurence of typing errors in different independent selections or successive selections made two or more times, and preventing the accumulation of fatigue or reducing the occurrence of stress attributable to the selections.

Means for the data execution include a hardware means and a software means. The hardware means include a key, a button, a switch, etc. The software means include a Graphic User Interface (GUI), an application (App), a window, an icon, an emoticon, an image, a picture, a shape, etc.

The data execution, includes data input. The objects 650 of the data input include a character, a number, a symbol, a special character, a special symbol, etc. For example, the character refers to one of the characters that are being used in the countries of the world.

Furthermore, the data execution includes data control. The objects 650 of the data control include a keyboard function, a mouse function, an information communication function, a search function, a play function, a motion function, a setting function, etc. The objects of the keyboard function or the mouse function include Mode, Enter, Space, F (function), Esc, Rack, Shift Ctrl (control), Alt, Tab, Caps Lock, Home, Del, Page, Capture, Pointing, Click, Scroll, Drag, Call, Zoom, Direction, Speed, Change, Return, etc. In this case, the objects of the pointing may include a display portion, a program, application software, etc. including the Internet, a document, a menu window or a popup window. The objects of the information communication function include a telephone, contact information, a message, a note, a clock, the Internet, etc. The objects of the smell function include Googling, a document, a file, a menu, content, etc. The objects of the play function include music, a removing image, voice, sound, broadcast, a movie, a game, a character, a camera, an image, etc. The motion function includes movement control such as the control of start, moving forward, moving rearward, temporary stop, stop, lifting, lowering, tilting, bending, rotation, jump, return, zigzag, protrusion and depressing, motion control, remote control, etc., direction control, variable direction control, or remote control function. The objects of the setting function include a user environment, an option, a symbol, reservation, etc. The data control includes the meaning “predetermined hardware or software is executed by a selection or indication of the means for data execution” or “a predetermined program operating in conjunction with predetermined hardware or software is executed by a selection or indication of the means for data execution.” However, the objects of the data input and the objects of the data control are not limited to the components of the data according to the present invention.

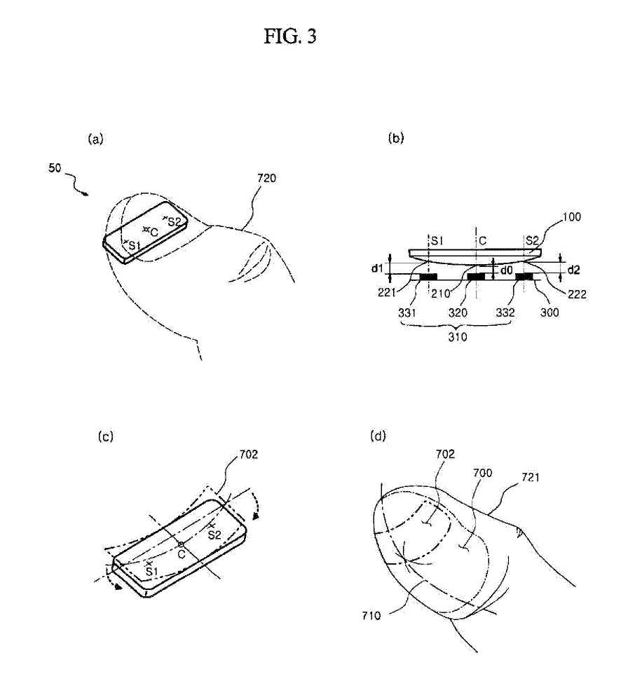

FIG. 3 is a diagram illustrating examples of the schematic configuration of the input module 50 according to an embodiment of the present invention and the configuration of a separation distance formed by the input module.

Referring to FIG. 3, the input module is configured such that a reference location C is centered on the selection unit 100 and side locations S1 and S2 are located on the one and other sides of the selection unit. The reference location and the side locations correspond to selection locations that am selected by the selection means in the selection unit

As shown in FIG. 3, in the selection unit, the reference location and the side locations are provided to be located within a range corresponding to a fingerprint region 700 on the basis of a fingerprint in the distal end portion of a single thumb 721.

Referring to FIG. 3, the corresponding region 702 is included in the fingerprint region. The corresponding region is a region where the overall top surface of the selection unit corresponds to the fingerprint of the finger (see FIGS. 3(c) and 3(d)) in the state in which the single finger 720 has been centered on the selection unit 100 (see FIG. 3(a)).

The reference location and the side locations may be configured to be spaced apart from each other by a predetermined distance along a single axis of the selection unit in one direction. The axis includes a single axis (a single lateral axis) in a lateral direction. The axis is a virtual line that is located along a single direction.

Referring to FIG. 3, in the input module, the reference location is, located at one point in the center portion of the selection unit, and the side locations include the first side location S1 located on one side of the selection unit and the second side location S2 located on the other side of the selection unit.

As shown in FIG. 3(b), in the input module, contact locations that correspond to selections of the reference location C and the side locations S1 and S2 via the selection means and come into contact with the corresponding sensors 310 of the sensor unit 300 are located at predetermined locations under the selection unit 100. The contact locations includes a reference contact location 210 located at a predetermined location under the reference location, a first contact location 221 located at a predetermined location under the first side location S1 of the side locations, and a second contact location 222 located at a predetermined location under the second side location S2 of the side locations.

Referring to FIG. 3(b), in the input module, a predetermined sensor unit 300 is provided at a location spaced from the bottom of;the selection unit 100 by a predetermined distance. The sensors 310 of the sensor unit includes a reference sensor 320, a first sensor 331, and a second sensor 332. The reference sensor 320 is located in the sensor unit under the reference contact location spaced apart from the reference contact location by a predetermined distance on the basis of the reference contact location 210, and is brought into contact with the reference contact location by selection via the selection means. The first sensor 331 is located in the sensor unit under the first contact location spaced apart from the first contact location by a predetermined distance on the basis of the first contact location 221, and is brought into contact with the first contact location by selection via the selection means. The second sensor 332 is located in the sensor unit under the second contact location spaced apart from the second contact location predetermined distance on the basis of the second contact location 222, and is brought into contact with the second contact location by selection via the selection means.

The sensor unit includes one or more sensors 320, 331 or 332.

For examples in the sensor unit, one or more sensors may be provided around the reference sensor 320 to be spaced apart from the reference sensor by a predetermined distance. In this case, a setting may be, made such that a signal generated by the one or more sensors may be processed as a predetermined signal generated by the reference sensor by selection via the selection means.

The sensors 310 of the sensor unit may be provided in the form of contact sensors. The contact sensors include tact switches, dome switches, rubber switches or contact switches, ere. The sensors include one or more of pressure sensors, tactile sensors or force sensors that detect pressure applied by the selection of the selection means or the force of the selection means. Furthermore, the sensors include PCB sensors that are formed on a PCB in the form of wiring in a predetermined pattern.

Referring to FIG. 3(b), the input module 50 is provided to have a predetermined separation distance across which the input module 50 is brought into contact by the selection of the selection means and is returned from the, contact location to its original location.

The separation distance may represent a stroke across which a contact via the selection and a return from the contact location to an original location are made.

Furthermore, the separation distance may he represented by the interval between two points that are formed such that the contact via the selection or the return is made.

That is, as shown in FIG. 3(b), in the input module, such separation distances may include: a reference interval d0 corresponding to a space along a single axis between a predetermined location 210 (a reference contact location) under the selection unit and the reference sensor 320 of the sensor unit that are located to be spaced apart by a predetermined distance along this axis vertically passing through the reference location C; a first interval d1 corresponding to a space along a single axis between a predetermined location 221 (first contact location) under the selection unit and the first sensor 331 of the sensor unit that are located to be spaced apart by a predetermined distance along this axis vertically passing through the first side location S1, and a second interval d2 corresponding to a space along a single axis between a predetermined location 222 under the selection unit and the second, sensor 332 of the sensor unit that are located to be spaced apart by a predetermined distance along this axis vertically passing through the second side location S2 (a second contact location).

In this case, in the input module, the reference interval d1 is configured to be smaller than each of the first interval d1 and the second interval d2. The first interval and the second interval may be configured to be the same interval or different intervals depending on the configuration of an embodiment.

The input module may be configured such that, when the reference location, the first side location or the second side location is selected, the reference contact location, the first contact location or the second contact location is moved in the direction of the separation distance, comes into contact with the sensor of the sensor unit corresponding to the selection, and is, returned to an original location. The returning means may provided between the selection unit and the sensor unit, or may be provided on the input module supporting the selection unit and the sensor unit or the predetermined location of a base provided with the input module. The returning means may include a soft member, an elastic member, a member having a repetitive feedback feature, a spring, or a composite member having one or more members. For example, the member may include rubber, silicon, synthetic rubber, synthetic resin, etc.

The data execution device 1 according to the present invention may enable data execution, assigned to a predetermined signal that is generated by the selection of the selection means in the input module 50, to be independently or successively performed.

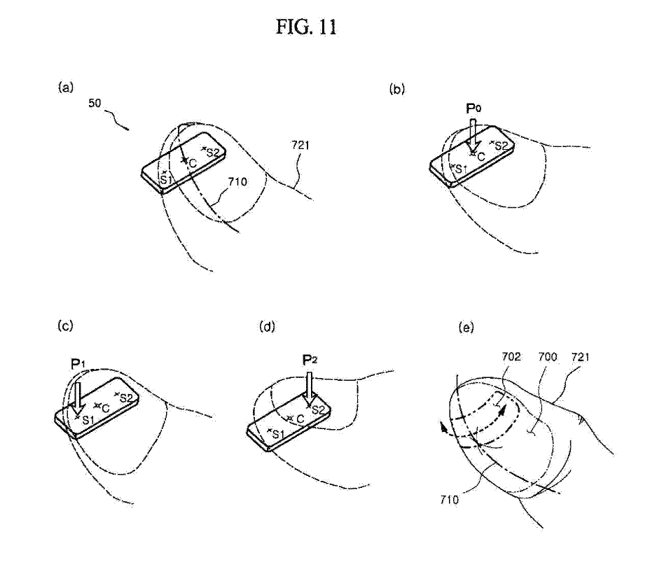

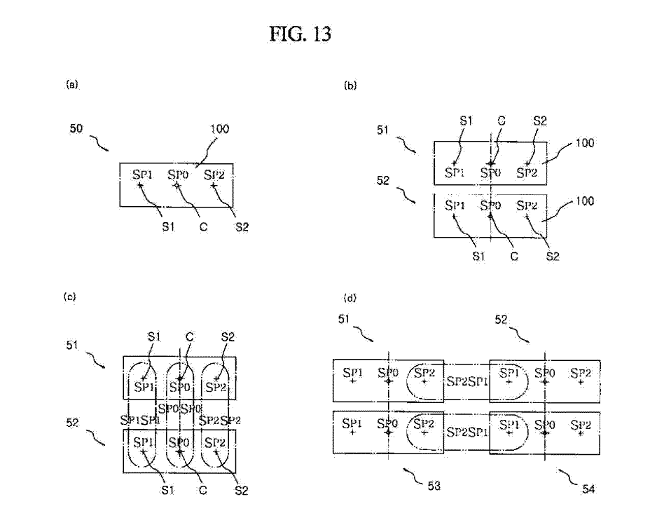

As an example, referring to FIG. 3(b), FIG. 11(b) and FIG. 13(a), data execution assigned to a predetermined reference signal SP0 may be independently or successively performed in the input module. In this case, the reference signal is a signal that is generated by the reference sensor 320 of the sensor unit 300 brought into contact with, the reference contact location 210 under the selection unit by the selection when the selection is performed by a single pressing operation P0 centered on the selection unit including the reference location C on the basis of a selection via a single finger located as shown in FIG. 11(a) in the selection unit 100 of the input module.

As another example, referring to FIGS. 3(b), 11(e), 11(d) and 13(a), data execution assigned to the predetermined side signals SP1 and SP2 may be independently or successively performed in the input module. In this case, the side signal is a signal that is generated by the first sensor 331 of the sensor unit 300 brought into contact with the first contact location 221 under the selection unit or by the second sensor 332 of the sensor unit brought into contact with the second contact location 222 under the selection unit by the selection when the selection is performed by a single pressing operation toward one or other side of the selection unit including the first side location S1 or second side location S2 on the basis of the selection of a single finger located as shown in FIG. 11(a) in the selection unit 100 of the input module.

In the input module, the different, selection locations S1, C and S2 selected by the selection means are located within a range corresponding to the fingerprint region 700 in the distal end position of a single thumb, and are located to be spaced apart from each other by a predetermined distance along a single axis in one direction within the selection unit 100 of the input module (see FIGS. 3 and 11), with the result that the reference location C, the first side location S1 and the second side location S2 are recognized as the selection locations of the center, one side and other side of the selection unit by the single finger located on the selection unit in the input module.

Furthermore, when the fingerprint center line 710 of the finger is centered on the selection unit on the basis of a single finger in the input module (see FIG. 3 or 11), the different independent selections or successive selections of the recognized different selection locations S1, C and S2 via the finger may be performed by a pressing operation in a form that moves within, the top surface of the selection unit (see the arrows shown in the drawing). The pressing operation may include one or more of a pressing-type operation, a rolling-type operation, and a tilting-type operation. Furthermore, the pressing operation may include a predetermined angle.

According to a feature attributable to the structure of the input module 50 or the selection unit 100 of the input module, the present invention is configured such that three selection locations (the first side location, the reference location, and the second side location) located on the selection unit are intuitively recognized in a one side-center-other side arrangement S1-C-S2 by a single finger. That is, the present invention enables data execution, which performs data input or data control via the selection, to be easily and rapidly performed in an independent or successive manner according to the above-described feature. Furthermore, the present invention enables different independent selections or successive selections of the three selection locations S1, C and S2 of the selection unit to be naturally performed by the recognition without separate learning. That is, the present invention enables the selection of one or more of the three selection locations S1, C and S2 to be naturally performed by a familiar selection operation via a single finger without separate learning in the state in which a user carries, grips and wears the device of the present invention, shifts or moves.

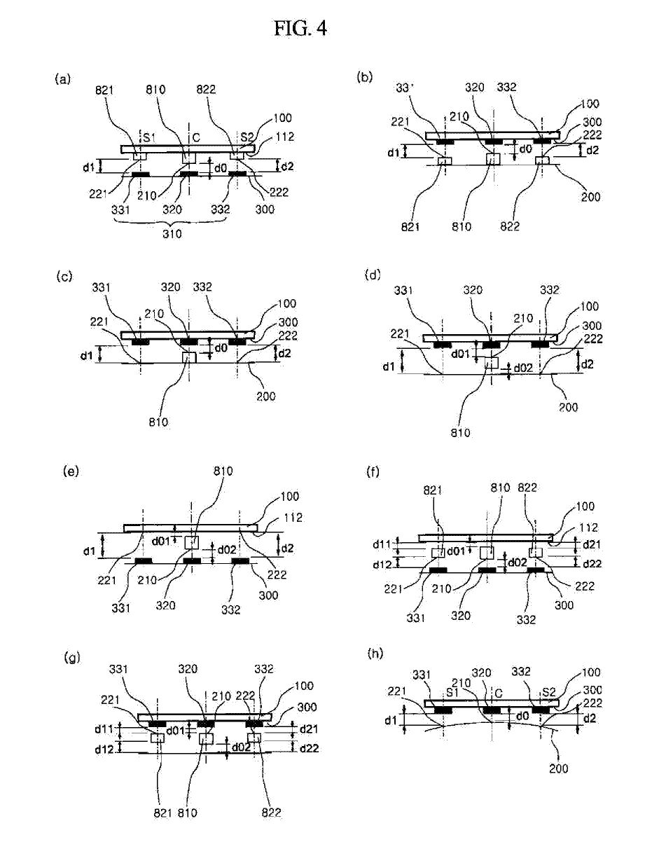

FIG. 4 is a diagram illustrating examples of various configurations of separation distances according to embodiments of the present invention different from that of FIG. 3.

As shown in FIG. 4, in an input module 50, at least one member may be provided between a selection unit 100 and the sensor 310 of a sensor unit 300. In the input module, the member includes a reference member 810 and side members.

In the input module, the reference member may be provided between the reference location C of the selection unit and the reference sensor 320 of the sensor unit.

Furthermore, the side members may include a first member 821 located between the first side location S1 of the selection unit and the first sensor 331 of the sensor unit, and a second member 822 located between the second side location S2 of the sensor unit and the second sensor 332 of the sensor unit.

The members may be composed of members having a soft, elastic or repetitive feedback property or composite members having one or more of the properties. For example, the members may include rubber, silicon, synthetic rubber, synthetic resin, etc.

In the input module, the at least one member may be configured in various forms.

As an example, in the input module, the reference member 810 may be provided between the reference location C and the reference sensor 320. In this case, in the input module, the separation distance “d0” or “d01+d02” under the reference location may be configured to be shorter than the separation distance “d1” under the first side location and the separation distance “d2” under the second side location by the reference member. Although the reference member is preferably composed of a single member, the reference member may be divided into a plurality of segments in an embodiment.

As another example, in the input module, a first member 821 may be provided between the reference member 810 and the first side location S1, and the first sensor 331, a second member 822 may be provided between the reference member and the second side location S2, and the second sensor 332, and the reference member, the first member and the second member may be provided together. In this case, in the input module, the separation distance “d01+d02” under the reference location is configured to be shorter than each of the separation distance “d11+d12” under the first side location and the separation distance “d21+d22” under the second side location by the reference member and the first member (or the second member), or the reference member, the first member and the second member. In the configuration of the separation distance, the separation distance “d11+d12” and the separation distance “d21+d22” may be configured to be the same or different Although each of the first member and the second member is preferably composed of a single member, it may be composed of a plurality of segments in an embodiment.

Referring to FIG. 4, the members 810, 821 and 822 of the input module may be provided in various sizes.

As an example, as shown in FIG. 4(d) or 4(g), the member may be provided to be spaced apart from each of a selection unit 100 and sensors 320, 331 and 332 by a predetermined distance and to be supported at a predetermined location between the selection unit and a contact unit 200. As shown in FIG. 4(e) or 4(f), the member may be provided to be spaced apart under the selection unit 100 by a predetermined distance and to be supported at a predetermined location between the selection unit and the sensor unit 300. The configuration of the support means may employ or adaptively employ a configuration identical to that of the above-described returning means.

As another example, as shown in FIG. 4(a), the member may be provided under an axis selection unit 100 that vertically passes the reference location C or side location S1 or S2.

In this case, the member may be configured to be integrated with the bottom 112 of the selection unit 100, or may be configured in a form that comes into close contact with the bottom.

As still another example, as shown in FIG. 4(b) or 4(c), the member may be provided on the contact unit 200 that is located to be spaced apart from the sensor unit 300 by a predetermined distance. In this case, the member may be provided at a predetermined location of the contact unit corresponding to each of the sensors, and may be configured to be integrated with the contact unit or in a form that comes into close contact with the contact unit

Referring to FIGS. 4, 11 and 13, when the selection is performed by a single pressing operation centered on of the selection unit 100 including the reference location C on the basis of selection via a single finger in the input module, a predetermined reference signal SP0 is generated in the reference sensor 320 in contact with one side of the reference member 810 by the selection.

Alternatively, when the selection is performed by a single pressing operation toward one or other side of the selection unit 100 including the first side location S1 or second side location S2 on the basis of selection via a single finger in the input module, a predetermined side signal SP1 or SP2 is generated in the first sensor 331 in contact with one side of the first member 821 or the second sensor 332 in contact with one side of the second member 822 by the selection.

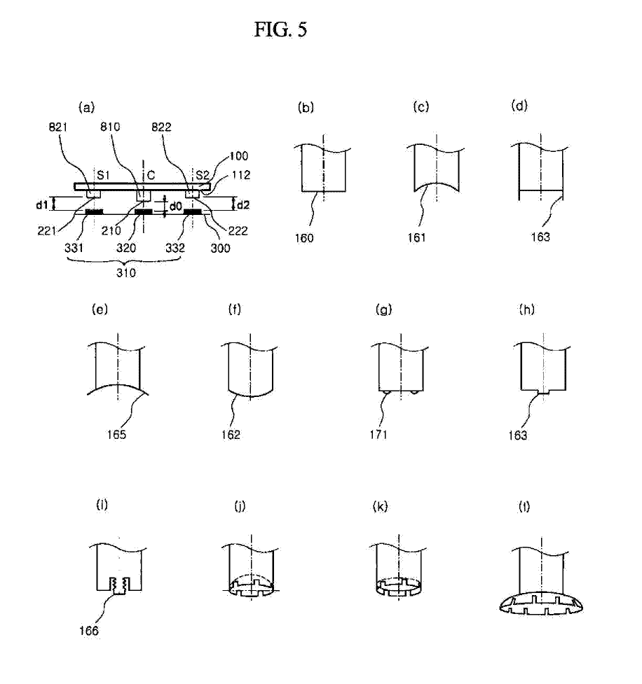

FIG. 5 a diagram illustrating an example of the configuration of a member provided at a predetermined location between a contact location and a sensor in the input module 50 according to an embodiment of the present invention.

As shown in FIG. 5, one side of at least one of a reference member 810 or side members 821 and 822 that come into contact with the sensor 310 of a sensor unit 300 when a selection is made via a selection means in the input module may be provided in the form of one or more shapes. The one side of the at least one may be provided to include at least one of a plane portion 160, a concave portion 161, a wing portion 165, a convex portion 162, a protrusion portion 163, a variable portion 166 or a protrusion 171. The protrusion portion 163 may be formed at a predetermined location including a corner of one side of the member (see FIG. 5(d)) or the center of one side of the member (see FIG. 5(h)). Referring to FIG. 5(g), one or more protrusions 171 may be formed at predetermined locations on one side end of the member. Referring to FIG. 5(i), the variable portion 166 at one side end of the member may be composed of a variable body including a wrinkled, bendable or flexible shape. Referring to FIGS. 5(j) to 5(l), one side end of the member may include one or more protrusion and depressed portions or one or more zigzag portions However, the above-described member does not limit the configuration of the input module according to the present invention.

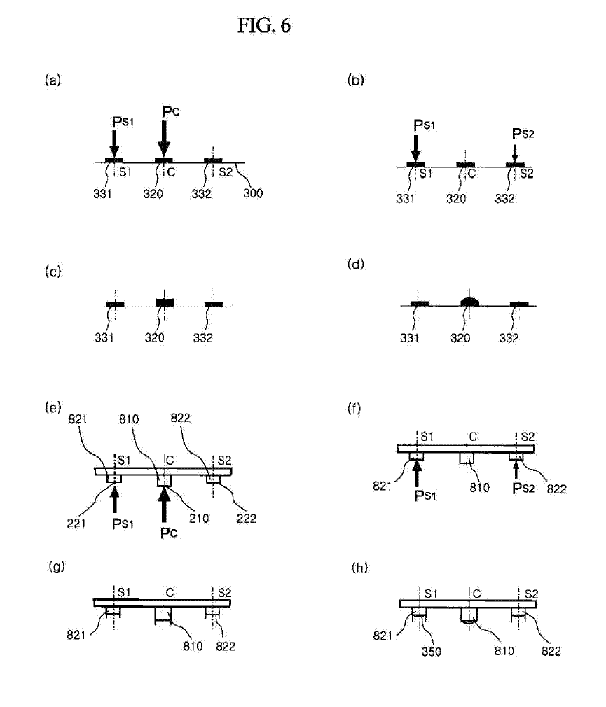

FIG. 6 is a diagram illustrating examples of various configurations of the input module 50 according to an embodiment of the present invention.

Sensor actuation pressures PC, PS1 and PS2 shown in FIG. 6 are pressures that act to cause the sensors 310 of a selection sensor unit 300 corresponding to selections of selection locations via a selection means in the input module 50 to generate predetermined signals. The selection locations correspond to a reference location C and side locations S1 and S2 at which the selections are made in the selection unit 100 of the input module.

Referring to FIG. 6, the sensor actuation pressures include a reference sensor actuation pressure PC and side sensor actuation pressures PS1 and PS2.

The reference sensor actuation pressure PC is a pressure that acts to cause the reference sensor 320 of the sensors 310 of the selection unit to operate and generate a reference signal SP0. The side sensor actuation pressures PSI and PS2 are pressures that act to cause the first sensor 331 or second sensor 332 of the sensors 310 of the selection unit to operate and generate side signals SP1 and SP2.

The reference sensor actuation pressure and the side sensor actuation pressures may be configured to be different.

For example, referring to FIG. 6(a), the reference sensor actuation pressure PC related to the reference sensor 320 may be provided to be higher than the side sensor actuation pressure PS1 related to the first sensor 331 or the side sensor actuation pressure PS2 related to the second sensor 332.

Alternatively, referring to FIG. 6(e), the reference sensor actuation pressure PC related to the reference sensor 320 corresponding to the selection of the center of the side sensor actuation pressure PS2 may be provided to be higher than the first sensor 331 or the second sensor 332 corresponding to the selection of the one or other side of the selection unit of the selection unit

The side sensor actuation pressures may be configured to be different from each other.

For example, referring to FIG. 6(b) or 6(f), the side sensor actuation pressure PS1 related to the first sensor 331 may be provided to be higher than the side sensor actuation pressure PS2 related to the second sensor 332.

Referring to FIGS. 6(c) and 6(d), in the input module, the reference sensor 320 generating the reference signal SP0 and the first sensor 331 and the second sensor 332 generating the side signals SP1 and SP2 may be provided to be the same or different depending on a predetermined criterion. The predetermined criterion includes at least one of the size, shape, type and material of the sensors.

For example, as shown in FIG. 6(c), the reference sensor 320 may be provided to be larger than the first sensor 331 and the second sensor 332. Alternatively, as shown in FIG. 6(d), the reference sensor may be provided in a dome shape unlike the first sensor and the second sensor.

Referring to FIGS. 6(g) and 6(h), in the input module, the reference member 810 and the side members 821 and 822 to be the same or different depending on a predetermined criterion. The predetermined criterion includes at least one of the size, shape, type and material of the members.

For example, as shown in FIG. 6(g), the reference member 810 may be provided to be larger than the side members 821 and 822.

Alternatively, as shown in FIG. 6(h), the reference member 810 formed to come into contact with the reference sensor 320 may be provided in a shape different from the shapes of the first member 821 and second member 822 of the side members farmed to come into contact with the first sensor 331 and the second sensor 332, respectively. That is, one side end of the reference member may be formed to have a predetermined curvature, and one side end of the first member and one side end of the second member may be formed to have predetermined protrusion portions, respectively. Furthermore, one side end of the first member and one side end of the second member may include predetermined conductors 350, respectively.

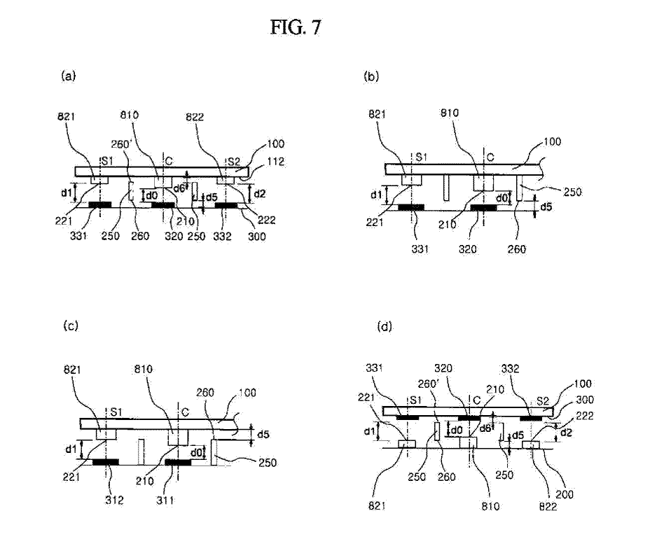

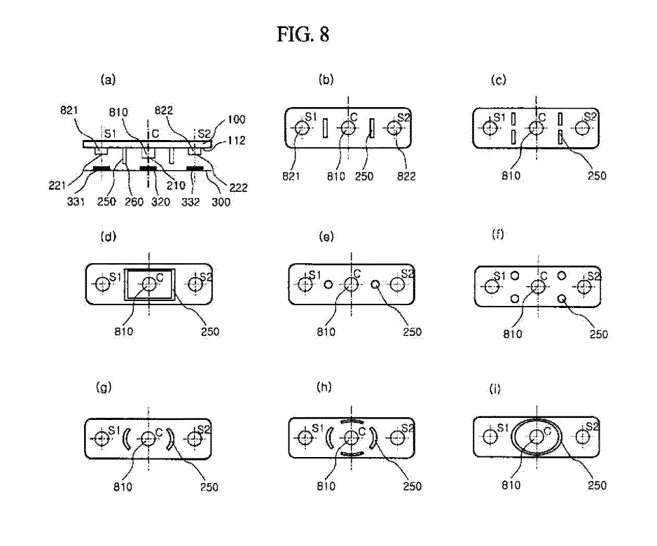

FIGS. 7 and 8 are diagrams illustrating examples of various configurations of location balancers 250 provided in input modules 50 according to embodiments of the present invention.

Referring to FIGS. 7 and 8, each of the input modules may be provided with at least one location balancer 250 having a predetermined width and, length.

In this case, the location balancers are located in a space between the bottom 112 of a selection unit 100 and a sensor unit 300, and are disposed at locations spaced apart from a reference location C toward side locations Si and S2 by a predetermined distance and between a reference location and side locations within the space. The location balancers function to balance movement so that the movement in which contact locations 210, 221 and 222 come into contact with the sensors 310 of the sensor unit or are returned can be performed along a separation distance in the input module.

Referring to FIG. 7, 8(b), 8(e) or 8(g), in the input module, the location balancers 250 may be provided to be located at respective predetermined locations spaced apart from a reference location C toward a first side location S1 and a second side location S2 by a predetermined distance and within a space between the bottom 112 of a selection unit 100 and a sensor unit 300.

Referring to FIGS. 7 and 8(a), in the input module, the location balancers 250 may include close contact portions so that they are located at one side ends in a vertical direction or one and other side ends in a vertical direction. The close contact portions are formed to be brought into close contact by the selection of a selection means.

As an example, in the input module 50 such as those shown in FIG. 7(b) or 7(c), the location balancers 250 may be provided such that close contact portions 260 are located at one side ends in a vertical direction.

In this case, referring to FIG. 7(b), in the location balancers, the close contact portions 260 at one side ends are brought into contact with predetermined locations of the sensor unit 300 by the selection of the selection means.

Alternatively, referring to FIG. 7(c), in the location balancers, the close contact portions 260 at one side ends are brought into contact with the predetermined locations of the bottom 112 of the selection unit 100 by the selection.

As another example, in the input module 50 such as that of FIG. 7(a), the location balancers 250 may be provided such that close contact portions 260 and 260′ are located at one and other side ends in a vertical direction.

In this case, referring to FIG. 7(a), the location balancer is formed such that the close contact portion 260 at the one side end comes into close contact with a predetermined location of the sensor unit 300 by the selection of the selection means, and the close contact portion 260′ at the other side end comes into close contact with a predetermined location on the bottom 112 of the selection unit 100 by the selection.

Alternatively, an input module 50, such as that of FIG. 7(d) may be provided with the location balancers 250.

In this case, the location balancer is formed such that a close contact portion 260 at one side end in a vertical direction comes into close contact with a predetermined location of a contact unit 200 by the selection of a selection means and a close contact portion 260′ at the other side end in the vertical direction comes into close contact with a predetermined location on the bottom 112 of the selection unit 100 by the selection. The contact unit is a component that is located to be spaced apart from the sensor unit by a predetermined distance and is provided to have the above-described separation distance in the input module.

Referring to FIG. 7(b), 7(c) or 8(a), in the input module, the location balancer 250 may be provided such that a close contact portion 260 at one side end in a vertical direction has a predetermined separation distance d5 to a sensor unit 300 or the bottom 112 of a selection unit 100.

Referring to FIG. 7(a), in the input, module, the location balancer 250 may be provided such that a close contact portion 260 at one side end in a vertical direction and a close contact portion 260′ at the other side end have predetermined separation distances d5 and d6 to a sensor unit 300 and the bottom 112 of a selection unit 100, respectively.

Alternatively, referring to FIG. 7(d), in the input module, the location balancer 250 may be provided such that a close contact portion 260 at one side end in a vertical direction and a close, contact portion 260′ at the other side end, have predetermined separation distances d5 and d6 to a contact unit 200 and a sensor unit 300, respectively.

In the input module such, as that of FIG. 7(a) or 7(d), the location balancer may be supported by a predetermined support means within a predetermined space such, as that shown in the drawing. The configuration of the support means may employ or adaptively employ the configuration of the above-described returning means.

Referring to FIG. 8, in the input module, the above-described location balancer 250 may be configured in various forms.

That is, the location balancer may be provided in a 3D dual rectangular shape shown in FIG. 8(b), a 3D multiple rectangular shape shown in FIG. 8(c), a 3D single box shape shown in FIG. 8(d), a 3D dual cylindrical shape shown in FIG. 8(e), a 3D multiple cylindrical shape shown in FIG. 8(f), a 3D dual curved shape shown in FIG. 8(g), a split hollow cylindrical shape shown in FIG. 8(h), or a hollow cylindrical shape shown in FIG. 8(i). Furthermore, the location balancer may be formed in a variable shape. The variable shape includes a wrinkled shape, a bendable shape, a zigzag shape or a protrusion and depression shape. However, the shape of the location balancer does not limit the configuration of the input module according to the present invention.

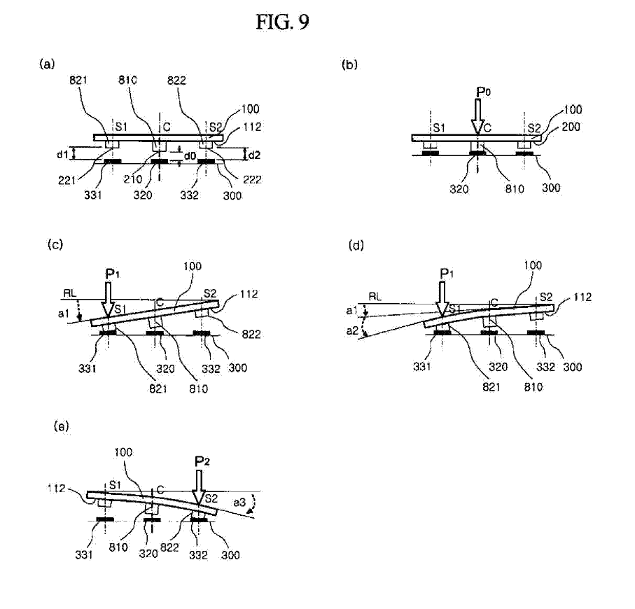

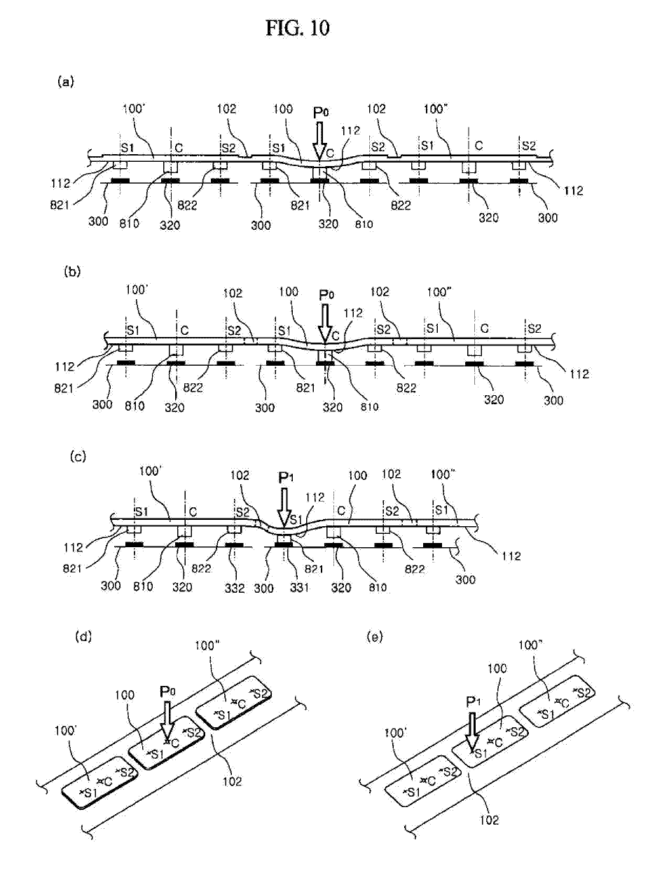

FIGS. 9 and 10 are diagrams illustrating examples of data execution based on the configuration of the selection unit 100 or the configuration of the selection unit according to an embodiment of the present invention.

In an input module 50 provided as shown in FIG. 9(a), the selection unit 100 may include at least one of an elastic member and a non-elastic member.

As an example, referring to FIG. 9(b), in an input module, the selection unit 100 may be composed of a non-elastic member.

That is, in the input module, on the basis of selection via a single finger along a single reference line RL passing through the selection unit in a lateral direction, even when the selection is performed toward one or other side of the selection unit composed of the elastic member (see P1 or P2), a predetermined portion of the one side or the other side is not inclined or bent downward from the reference line (see the dotted arrow a1 indicative of only the movement of a location in FIG. 9(c) or 9(d)).

As another example, unlike in FIG. 9(b), in an input module, a selection unit 100 may be composed of an elastic member.

That is, referring to FIG. 9(b), 9(d) or 9(e), in the input module, on the basis of selection via a single finger along a single reference line RL passing through the selection unit in a lateral direction, when the selection is performed toward one or other side of the selection unit composed of the elastic member (see P1 or P2), a predetermined portion of the one side or the other side may be inclined or bent downward from the reference line within a predetermined angle (see the dotted arrow a2 or a3). When the selection is released, the inclined or bent predetermined portion, may be returned to its original location. The returning may be achieved by the characteristic of the elastic member having a repetitive feedback feature. In this case, even when the selection is performed while being centered on the selection unit composed of the elastic member (see P0), one or other side of the selection unit is not inclined or bent downward from the reference'line and thus a signal is not generated. That is, the selection unit composed of the elastic member has the characteristic of flexibly responding to the selection of the selection means that is performed for one or other side of the selection unit.

The sensor actuation pressures of the sensors 310 corresponding to the selection that is performed in the above-described input module may be common sensor actuation pressures.

The selection unit 100 according to the above-described embodiment of the present invention may include a plurality of selection units 100, 100′ and 100.″

Referring to FIG. 10, in the selection units, one selection unit and the other selection unit that are spaced apart by a predetermined distance in at least one direction are located to be connected by a predetermined connection frame 102.

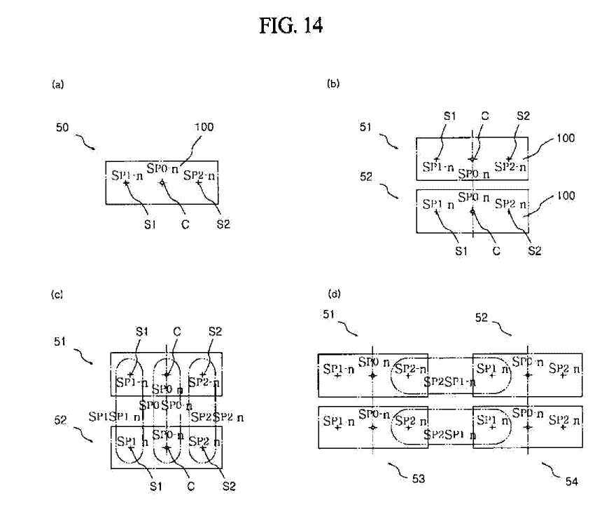

Referring to FIG. 11, in the input modules 50 according the above-described present invention, a reference signal SP0 or a side signal SP1 or SP2 may be successively generated based on a difference in the number, of selections or a difference in the strength of pressing pressure in the selection of the, selection means for a reference location C or side locations S1 and S2. Referring to FIGS. 13 and 14, the successively generated plurality of reference, signals may be represented by SP0-n, and the successively generated plurality of side signals may be represented by SP1-n or SP2-n.

The signal processing may be performed using various methods.

For example, the signal processing may be performed based on a predetermined set time value.

That is when the time interval of each signal of the plurality of reference signals SP0-n or plurality of side signals SP1-n or SP2-n falls within the set time value, a predetermined control unit 500 processes the reference signals SP0-n as a new single reference signal different from each signal of the reference signals or processes the side signals SP1-n or SP2-n as a new single side signal different from each signal of the side signals.

Alternatively, when the time interval of each signal of the reference signals or side signals exceeds the set time value, the control unit processes the reference signals as independently successively generated individual reference signals and processes the side signals as independently successively generated individual side signals.

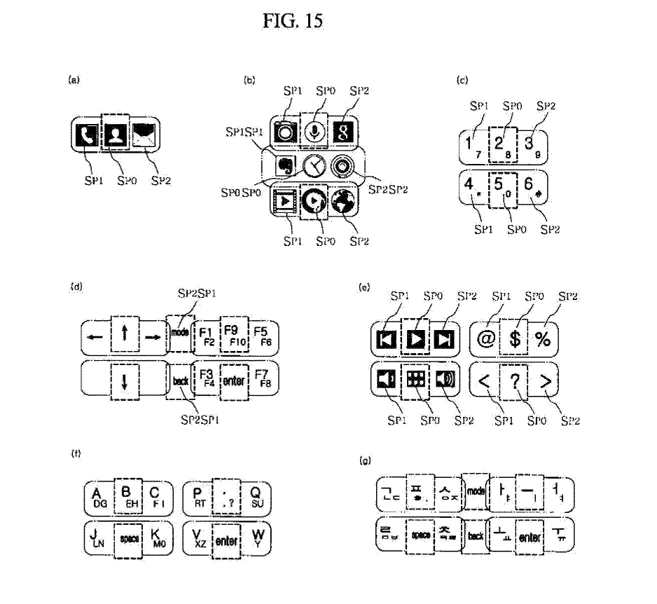

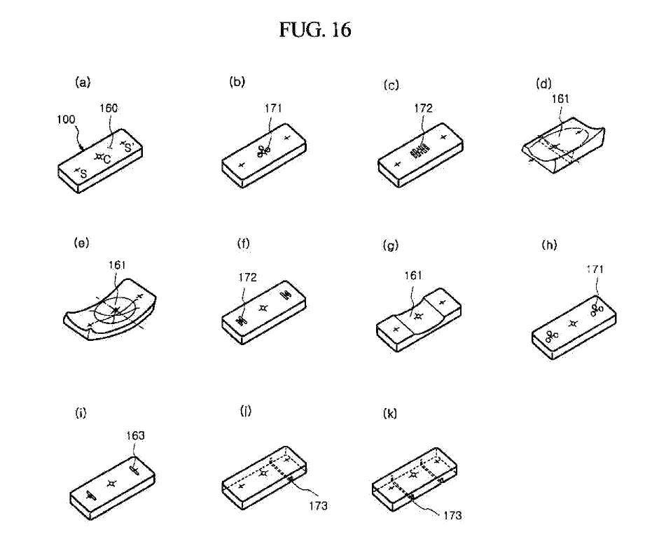

FIG. 15 is a diagram illustrating examples of the configuration of data, assigned to a signal according to the present invention shown in FIG. 13 or 14, or various embodiments of data execution.

As an example, referring to the diagram and FIG. 15(a), data assigned to a reference signal “SP0” according to the present invention is the “contact information” of the information communication function among the objects of the above-described data control. That is, the control unit 500 outputs the contact information data of the information communication function or the electrical signal of the contact information data corresponding to the reference signal “SP0” to an electronic device, thereby enabling data execution including various functions related to the “contact information” to be performed.

As another example, retelling to the diagram and FIG. 15(a), data assigned to a side signal “SP1” according to the present invention is the “telephone of the information communication function among the objects of the, above-described data control. That is, the control unit 500 outputs the telephone data of the information communication function corresponding to the side signal “SP1” or the electrical signal of the telephone data to an electronic device, thereby enabling data execution including various functions related to the “telephone” to be performed.

As still another example, referring to the diagram and FIG. 15(a), data assigned to a side signal “SP2” according to the present invention is the “message” of the information communication function among the objects of the above-described data control. That is the control unit 500 outputs the message data of the information communication function corresponding to the side signal “SP2” or the electrical signal of the message data to an electronic device, thereby enabling data execution including various functions related to the “message” to be performed.

The input module of the present invention may be configured to be different from the above-described embodiment of FIG. 3(b).

As an example, in the configuration of an input module 50 such as that of the embodiment of FIG. 3(b), a sensor unit 300 is provided on the bottom of a selection unit 100, and a contact unit 200 is provided at a location spaced apart from the sensor unit by a predetermined distance.

The schematic configuration of the input module is described with reference to FIG. 4(h).

That is, in the input module, sensors 310 corresponding to selections of a selection means for a reference location C or side locations S1 and S2 are located in the sensor unit on the bottom of the selection unit and the sensors include a reference sensor 320 located on the bottom of the reference location and a first sensor 331 located under a first side location S1 and a second sensor 332 located under a second side location S2 among the side locations.

Furthermore, contact locations that correspond to the selections of the reference location C and the side locations S1 and S2 and come into contact with the corresponding sensors 310 of the sensor unit are located at predetermined locations on the top of the contact unit. The contact locations include a reference contact location 210 that is located at a predetermined location between the bottom of the reference sensor and the top of the contact unit and is brought into contact with the reference sensor by the selection, a first contact location 221 that is located at a predetermined location between the bottom of the first sensor and the top of the contact unit and comes into contact with the first sensor by the selection, and a second contact location 222 that is located at a predetermined location between the bottom of the second sensor and the top of the contact unit and comes, into contact with the second sensor by the selection.

The input module 50 is provided to have a predetermined separation distance across which the input module 50 is brought, into contact by the selection of the selection means and is returned from the contact location to its original location.

The separation distance may represent a stroke across which a contact via the selection and a return from the contact location to an original location are made.

Furthermore, the separation distance may be represented by the interval between two points that are formed such that the contact via the selection or the return is made.

That is in the input module, the separation distances may include a reference interval d0 corresponding to a space along a single axis between the reference sensor and the contact unit that are located to be spaced apart by a predetermined distance along this single axis vertically passing through the reference location C; a first interval d1 corresponding to a space along a single axis between the first sensor and the contact unit that are located to be spaced apart by a predetermined distance along this single axis vertically passing through the first side location; and a second interval d2 corresponding to a space along a single axis between the second sensor and the contact unit that are located to be spaced apart by a predetermined distance along this single axis vertically passing through the second side location S2.

In this case, in the input module, the reference interval is configured to be shorter than each of the first interval and the second interval. The first interval and the second interval may be configured to be the same or different depending on the configuration of an embodiment.

In the input module, when the reference location, the first side location or the second side location is selected, the reference sensor, the first sensor or the second sensor is moved in the direction of the separation distance, is brought into contact with the contact location of the contact unit corresponding to the selection, and is returned to its original location.

The returning means may employ or adaptively employ the configuration of the returning means described in conjunction with the embodiment of FIG. 3(b).

The above-described data execution device 1 according to the present invention is configured to independently or successively perform data execution assigned to a predetermined signal that is generated by the selection of the selection means in the input module 50.

As au example, in the input module, data execution assigned to a predetermined reference signal SP0 may be independently or successively performed. That is, the reference signal is a signal that is generated by the reference sensor 320 of the sensor unit 300 in contact with the reference contact location 210 by the selection when the selection is performed by a single pressing operation P0 while being centered on the selection unit including the reference location C on the basis of selection via a single finger located as shown in FIG. 11(a) in the selection unit 100 of the input module.

As another example, in the input module, data execution assigned to a predetermined side signal SP1 or SP2 may be independently or successively performed. That is, the side signal is a signal that is generated in the first sensor 331 of the sensor unit 300 in contact with the first contact location 221 or the second sensor 332 of the sensor unit in contact with the second contact location 222 by the selection when the selection is performed by a single pressing operation toward one or other side of the selection unit including the first side location S1 or second side location S2 on the basis of selection via a single finger located as shown in FIG. 11(a) in the input module of the selection unit 100.

In the input module, at least one member may be provided between the sensor and the contact unit. That is, in the input module, the members include a reference member 810 and side members.

In the input module, the reference member may be provided between the reference sensor and the contact unit.

Furthermore, the side members may include a first member 821 located between the first sensor and the contact unit and a second member 822 located between the second sensor and the contact unit.

The members may employ or adaptively employ the configurations of the corresponding members in the above-described embodiment.

In the input, module, at least one of the members may be configured in various forms.

As an example, in the input module, the reference member 810 may be provided between the reference sensor 320 and the contact unit. In this ease, in the input module, the separation distance “d01+d02” under the reference location may be configured to be shorter than each of the separation distance “d1” under the first side location and the separation distance “d2” under the second side location by the reference member. Although the reference member is preferably provided in an integrated form, it may be provided in the form of a plurality of segments in an embodiment.

As another example, in the input module, the first member 821 may be provided between the reference member 810 and the first sensor 331, and the contact unit, the second member 822 may be provided between the reference member and the second sensor 332, and the contact unit, and the reference member, the first member and the second member may be provided together. In this case, in the input module, the separation distance “d01+d02” under the reference location may be configured to be shorter than each of the separation distance “d11+d12” under the first side location and the separation distance “d21+d22” under the second side location by the reference member and the first member (or the second member) or the reference member, the first member and the second member.

In the configuration of the separation distance, the separation distance “d11+d12” and the separation distance “d21+d22” may be configured to be the same or different Although each of the first member and the second member is configured in the form of an integrated form, it may be provided in the form of a plurality of segments in an embodiment In the input module, the reference member 810 and the side members 821 and 822 may be provided to be the same or different depending on a predetermined criterion. The predetermined criterion includes at least one of the size, shape, type and material of the members. Since the more detailed configurations of the components of the input module may employ or adaptively employ the configurations of corresponding components in the above-described embodiments, descriptions thereof are omitted.

FIG. 16 is a diagram illustrating examples of various configurations of an input module 50 according to an embodiment of the present invention or a selection unit 100 provided in the input module.

Referring to FIG. 16, the input module or the selection unit is provided based on a predetermined criterion, and the predetermined criterion includes at least one of a size, a shape, a member or a material. Furthermore, the shape includes at least one of a plane portion 160, a concave portion 161, a protrusion 171, a line 172, a groove 173, a protrusion portion 163, or an asymmetric shape (see FIG. 16(d) or 16(e)). The predetermined criterion does not limit the configuration of the input module according to the present invention.

The input module 50 of the above-described present invention may be provided as a plurality of input modules 51, 52, . . . at predetermined locations.

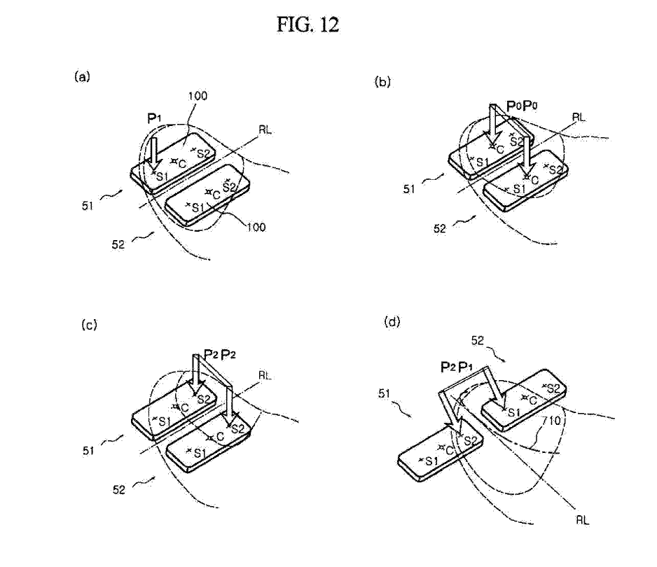

Referring to FIG. 12, the input modules arc arranged to be located to be spaced apart from each other by a predetermined distance in at least one direction, an may be configured in various forms. Since signals generated by selection via the selection means, the processing of the signals or the performance of execution assigned to the signals in the data selection units 100 of the input modules may employ or adaptively employ corresponding items in the above-described embodiments, descriptions thereof are omitted.

Referring to FIGS. 12 to 15, a plurality of different signals generated by the selection may be configured to be processed in the input modules 51, 52, . . . unlike in the above-described embodiments.

As an example, referring to FIGS. 12(b) and 13(c), the input module of the present invention may include a first input module 51 and a second input module 52 spaced apart by a predetermined distance in a vertical direction, and a single reference line RL may be located between the first input module and the second input module in a lateral direction. In this case, when selection via a single finger is performed by a single pressing operation for the center of the selection unit 100 of the first input module and the center of the selection unit 100 of the second input module based on the reference line, the reference location C of the selection unit of the first input module and the reference location C of the selection unit of the second input module are selected by the finger. By this selection, the generation of a single reference signal SP0 in the reference sensor 320 in contact with the reference contact location 210 of the first input module and the generation of another single reference signal SP0 in the reference sensor 320 in contact with the reference contact location 210 and the second input module are performed together. In this ease, the single reference signal and the other single reference signal are processed as a third reference signal “SP0SP0,” i.e., a new single reference signal, in a predetermined control unit 500 based on the predetermined set values of a plurality of signals.

As another example, referring to FIGS. 12(c) and 13(c), the input module of the present invention may include a first input module 51 and a second input module 52 spaced apart in a vertical direction by a predetermined distance, and a single reference line RL may be located between the first input module and the second input module in a lateral direction. In this case, when selection via the single finger is performed by a single pressing operation for one side of the selection unit 100 of the first input module and one side of the selection unit 100 of the second, input module based on the reference line, the first side location S1 of the selection unit of the first input module and the first side location S1 of the selection unit of the second input module are selected by the finger. By the selection, the generation of a single one side signal SP1 in the first sensor 331 in contact with the first contact location 221 of the first input module and the generation of another single one side signal SP1 in the first sensor 331 in contact with the first contact location 221 of the second input module are performed together. In this case, the single one side signal and the other single one side signal are processed as a third reference signal “SP1SP1,” i.e., a new single reference signal, in a predetermined control unit 500 based, on the predetermined set values of a plurality of signals.

Alternatively, when selection via a single finger is performed by a single pressing operation for the other side of the selection unit of the, first input module and the other side of the selection unit of the second input module in the above-described configuration of the first input module 51 and the second input module 52 based on the reference line, the second side location S2 of the selection unit of the first input module [symbol] and the second side location S2 of the selection unit of the second input module are selected together by the finger. By the selection, the generation of one other side signal SP2 in the second sensor 332 in contact with the second contact location 222 of the first input module and the generation of another other side signal SP2 in the second sensor 332 in contact with the second contact location 222 of the second input module are performed together. In this case, the single other side signal and the other other side single am processed as a third reference signal “SP2SP2,” i.e., a new single reference signal, in a predetermined control unit 500 based on the predetermined set values of a plurality of signals.

As still another example, referring to FIGS. 12(d) and 13(d), the input module of the present invention may include a first input module 51 and a second input module 52 spaced apart by a predetermined distance in a lateral direction, and a single reference line RL may be located between the first input module and the second input module in a vertical direction. In this case, when selection via a single finger is performed by a single pressing operation for the other side of the selection unit 100 of the first input module and one side of the selection unit 100 of the second input module based on the reference line, the second side location S2 of the selection unit of the first input module and the first side location S1 of the selection unit of the second input module are selected together by the finger. By the selection, the generation of a single other side signal SP2 in the second sensor 332 in contact with the second contact location 222 of the first input module and the generation of a single one side signal SP1 in the first sensor 331 in contact with the first contact location 221 of the second input module are performed together. In this ease, the single other side signal, and the single one side signal or the single one side signal and the single other side signal are processed as a third reference signal “SP2SP1,” i.e., a new single reference signal, in a predetermined control unit 500 based on the predetermined set values of a plurality of signals.

Alternatively, when selection via a single finger is performed by a single pressing operation for one side of the selection unit of the first input module and the other side of the selection unit of the second input module based on the reference line in the first input module 51 and second input module 52 of the above-described configuration, the first side location S1 of the selection unit of the first input module and the second side S2 of the selection unit of the second input module are selected together by the finger. By the selection, the generation of a single one side signal SP1 in the first sensor 331 in contact with the first contact location 221 of the first input module and the generation of a single other side signal SP2 in the second sensor 332 in contact with the second contact location 222 of the second input module are performed together. In this case, the single other side signal and the single one side signal or the single one side signal and the single other side signal are processed as a third reference signal “SP1SP2,” i.e., a new single reference signal, in a predetermined control unit 500 used on the predetermined set values of a plurality of signals.

In the first input module 51 and the second input module 52 configured as shown in FIG. 12(d), the separation distance under the second side location S2 of the first input module and the separation distance under the first side location S1 of the second input module are configured to be different based on the separation distance of the above-described embodiment. Alternatively, in the input module, the separation distance under the second side location S2 of the first input module and the separation distance under the first side location S1 of the second input module are configured to be the same in an embodiment.

In the first input module 51 and the second input module 52 configured as shown in FIG. 12(a), various pieces of data may be assigned to a signal that is generated by selection according to the present invention.

As an example, referring to FIGS. 13(c) and 15(b), in the first input module, the “voice” of the play function among the objects of the above-described data control may be assigned to the reference signal “SP0,” the “camera” of the play function among the objects of the above-described data control may be assigned to the side signal “SP1,” and the “Googling” of the search function among the objects of the above-described data conned may be assigned to the side signal “SP2.”

Furthermore, in the second input module, the “music” of the play function among the objects of the above-described data control, may be assigned to the reference signal “SP0,” the “moving image” of the play function among the objects of the above-described data control may be assigned to the side signal “SP1,” and the “Internet” of the information communication function among the objects of the above-described data control may be assigned to the side signal “SP2.”

As another example, referring to FIGS. 13(c) and 15(b), in the first input module and the second input module, the “clock” of the information communication function among the objects of the above-described data control may be assigned to the third reference signal “SP0SP0,” the “note” of the information communication function among the objects of the above-described data control may be assigned to the third side signal “SP1SP1,” and the “user environment” of the setting function among the objects of the above-described data control may be assigned to the third side signal “SP2SP2.”

As still another example, referring to FIGS. 13(b) and 15(c), in the first input module and the second input module, the objects of data input may be assigned in the form of a number and a symbol. That is in the first input module, the numbers “2 and 8” may be assigned to the reference signal “SP0,” the numbers “1 and 7” may be assigned to the side signal “SP1,” and the number “6” and the symbol “#” may be assigned to the side signal “SP2.”

Referring to FIGS. 15(d) to 15(g), the input module 50 of the above-described present invention may include four input modules 51, 52, 53 and 54.

That is the four input modules, i.e., a first input module 51, a second input module 52, a third input module 53 and a fourth input module 54, may be arranged to be spaced apart from each other by a predetermined distance in a lateral direction and in a vertical direction.

The selection performed in the selection units 100 of the input modules by the selection means, signals generated in the sensors 310 of the sensor units 300 in response to the selection, or data execution assigned to the signals may employ or adaptively employ corresponding selection and signals in the above-described embodiments.

As an example, the four input modules 51, 52, 53 and 54 may be configured, as shown in FIG. 15(d).

Referring to FIGS. 13(d) and 15(d), in the first input module 51 and the second input module 52, the “mode” of the keyboard or mouse function among the objects of the above-described data control may be assigned to the third side signal “SP2SP1.” The mode may include various function, such as mode selection, mode change, mode return, character selection, character input, special character selection, special character input, symbol selection, symbol input., emoticon selection, emoticon input, direction selection, direction control, etc.

As another example, in the four input modules 51, 52, 53 and 54 configured as shown in FIG. 15(e), referring to FIGS. 13(d) and 15(e), in the first input module 51, the “start” of the motion function among the objects of the above-described data control may be assigned to the reference signal “SP0.” That is, the control unit 500 outputs the start data of the motion function corresponding to the reference signal “SP0” or the electrical signal of the start data to an electronic device, thereby enabling data execution including a function related to the “start” ID be performed.

As still another example, referring to FIG. 15(f), data execution for the alphabet “A” of the character among the objects of the above-described data input and the “enter” of the keyboard function among the objects of the data control is described. In this case, the four input modules 51, 52, 53 and 54 shown in FIG. 15(f) are configured in a form shown in FIG. 13(d). First, when selection via a single finger is performed by a single pressing operation toward the one side S1 of the selection unit 100 of the first input module 51 (P1; see FIG. 12(a)), a predetermined side signal SP1 is generated in a first sensor 331 in contact with the first contact location 221 of the first input module by the selection. Thereafter, when the selection is performed by a single pressing operation toward the center C of the selection unit 100 of the fourth input module 54 (P0; see FIG. 11(b)), a predetermined reference signal SP0 is generated in a reference sensor 320 in contact with the reference contact location 210 of the fourth input module by the selection. In this case, the data assigned to the side signal “SP1” is the alphabet “C” of the character among the objects of the above-described data input, and the data assigned to the reference signal “SP0” is the “enter” of the keyboard function among the objects of the above-described data input. That is, the control unit 500 sequentially outputs the “C” data of the alphabet (or the electrical signal of the “C” data) and the “enter” data of the keyboard function (or the electrical signal of the “enter” data) to an electronic device, thereby enabling the “C” to be displayed on the display unit 600 or display portion 610 of the electronic device.

As still another example, referring to FIG. 15(g), data execution for the Korean characters “ [symbol] ” of the character among the objects of the above-described data input is described. In this case, the four input modules 51, 52, 53 and 54 shown in FIG. 15(g) are configured in a form shown in FIG. 13(d). First, when selection via a single finger is performed by a single pressing operation toward the center C of the selection unit 100 of the first input module 51 (P0; see FIG. 11(b), a predetermined reference signal SP0 is generated in the reference sensor 320 in contact with the reference contact location 210 of the first input module by the selection. Thereafter, when the selection is performed by the single pressing operation toward the one side S1 of the selection unit 100 of the second input module 52 (P1; see FIG. 12(a)), a predetermined side signal SP1 is generated in the first sensor 331 in contact with the first contact location 221 of the second input module by the selection. In this caw the data assigned to the reference signal “SP0” is the Korean character “ [symbol] ” of the character among the objects of the above-described data input, and the data assigned to the side signal “SP1” is the Korean character “ [symbol] ” of the character. That is, the control unit 500 sequentially outputs data of the Korean character “ [symbol] ” (or the electrical signal of the “ [symbol] ” data) and the data of the Korean character “ [symbol] ” (or the electrical signal of the ” [symbol] ” data) to an electronic device, thereby enabling the Korean character “ [symbol] ” of the “ [symbol] ” and “ [symbol] ” to be displayed on the display unit 600 display portion 610 of the electronic device.

Referring to FIGS. 13 and 14, since signal processing adapted to process a plurality of signals successively generated by the selection of the selection means in a plurality of input modules 51, 52, . . . of the present invention may employ or adaptively employ corresponding signal processing in the above-described embodiment, detailed descriptions thereof are omitted.

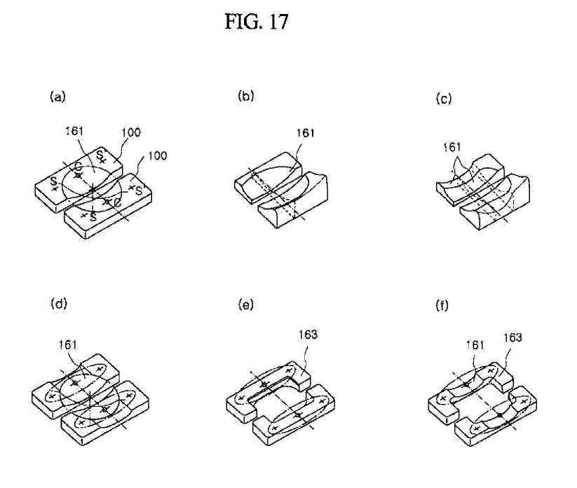

FIG. 17 is a diagram illustrating examples of various configurations of a plurality of input modules or the selection units of the input modules according to embodiments of the present invention.

As shown in FIG. 17, the configurations may employ or adaptively employ the various configurations of the input modules 50 of the above-described embodiments or the selection units 100 provided in the input modules.

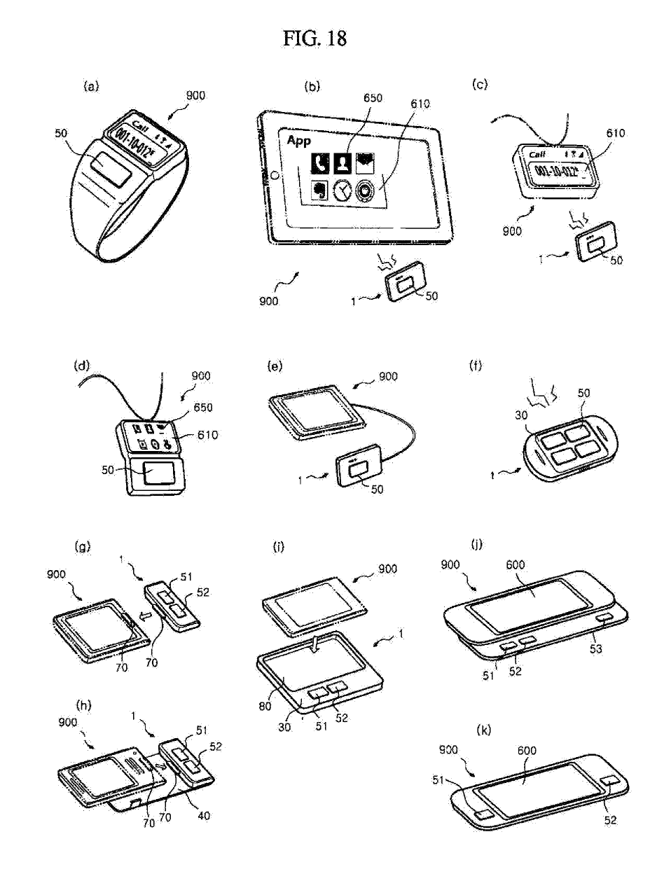

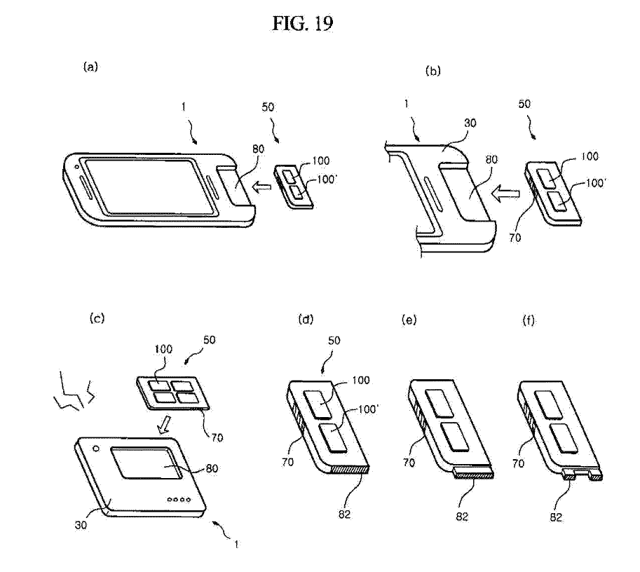

FIGS. 18 and 19 are diagrams illustrating examples of the configuration and application of a data execution device 1 and an input, module 50 according to an embodiment of the present invention.

Referring to FIG. 18 or 19, the input module may be detachably provided on the body 30 of the execution device 1 that performs the data execution.

Alternatively, the execution device or the body may include a fastening portion 80 at a predetermined location.

The execution device may be coupled, to a predetermined electronic device 900 in a wired or wireless mariner. A wireless-type transmission and reception means may include RF, Bluetooth, IrDA, ZigBee, SWAP, Wi-Fi and Li-Fi means, etc.

A fastening means for fastening the input module and the body to each other is provided at one or more predetermined locations of the input module and the body, and the fastening means includes one or more fastening members 82 among a protrusion, a groove, a slot, a guide, a latch, a hook, a holder 40, a band, and a Velcro tape. The fastening member may be configured to include at least one of a concave portion, a convex portion, a wing portion, a protrusion portion, and a variable portion. The variable portion may include one or more of wrinkled, protrusion and depression, flexible and zigzag shapes.

Furthermore, a terminal 70 for transferring the predetermined signals of the input module or the execution device or the transfer signals of data assigned to the signals may be provided at predetermined locations of the input module and the body.

According to the above-described features, the present invention can be easily applied to various types of electronic devices including a wearable device, a variable device, an Internet of Things (IoT) device, a composite device, etc., can be easily configured in the form of a detachable or portable accessory in each of the electronic devices, and can, provide the opportunity of configuring more various devices and an more improved user environment for data execution to a user in the field of data execution devices. That is, the data execution device or input module of the present invention provides the effect of further increasing industrial usability in an electronic device field in which one or more of data input and data control are performed.

The above-described embodiments of the present invention are merely some of various embodiments of the present invention. That is, the selection locations of the selection unit in which selection is performed in the above-described input module of the present invention are located within a range corresponding, to the fingerprint of a single thumb, and a separation distance under the center of the selection unit is configured to be shorter than a separation distance under each of one and other sides of the selection unit, thereby enabling the selection locations to be intuitively recognized by a single finger, and enabling different independent selections or successive selections for the recognized selection locations to be easily and rapidly executed. It will be apparent that various embodiments included in the technical spirit of a data execution device having the above-described input module are included in the range of protection of the present invention.

### INDUSTRIAL APPLICABILITY

The present invention relates to a data execution device, and the data execution device according to the present invention includes at least one input module, including a selection unit having three different selection locations at which selections are made by a finger, i.e., one selection means, within a range corresponding to the fingerprint of a single thumb and a sensor unit having sensors which generate signals in response to the selections. A reference location and side locations corresponding to selection locations at which the selections are performed are located to be spaced apart from each other by a predetermined distance along a single axis in one direction within the selection unit within a range corresponding to a fingerprint region in the distal end portion of a single thumb, and the reference interval of separation distances between the above-described three selection locations of the selection unit in the input module [symbol] corresponding location is configured to be shorter than each of first and second intervals.

According to the same characteristic, in the present invention, the three selection locations (the first side location, the reference location, and the second side location) can be intuitively recognized by a single finger in a one side-center-other side arrangement in the selection unit, independent or successive selections of the recognized selection locations can be naturally performed by the minute movement of the single finger with requiring separate learning, and the present invention can be easily applied to various types of electronic devices including a wearable device, a variable device, an Internet of Things (IoT) device, a composite device, etc. and can be easily configured in the form of a detachable or portable accessory in each of the electronic devices.

That is, the data execution device or input module of the present invention corresponds to an invention having high industrial usability in that it can provide the opportunity of configuring more various devices and an more improved user environment for data execution to a user in the field of the data execution devices of electronic devices that perform one or more of data input and data control.

1. A data execution, device, in which selection via a selection means is performed in a selection unit and data execution assigned to a signal generated by the selection is performed, wherein:
at least one input module, including a selection unit configured to enable a selection via a finger, which is one of the selection, means, to be performed and configured to have a predetermined width and length, and a sensor unit configured to have sensors generating signals in response to the selection, is included;
in the input module, the selection unit includes a single selection unit;
a reference location and side locations corresponding to selection locations at which the selection is performed in the selection unit are provided to be located within a range corresponding to a fingerprint region on the basis of a fingerprint in a distal end portion of a single thumb, the reference location and the, side locations are located to be spaced apart from each other by a predetermined distance along a single lateral axis within the selection unit, the reference location is located at one point at a center of the selection unit, and the side locations include a first side location located on one side of the selection unit and a second side location located on a remaining side of the selection unit;
contact locations that correspond to the selection of the reference location and the side locations and come into contact with sensors of the sensor unit are located at predetermined locations under the selection unit;
the contact locations include a reference contact location located at a predetermined location under the reference location, a first contact location located at a predetermined location under the first side location, and a second contact location located at a predetermined location under the second side location;
the sensor unit is provided at a location spaced apart from a bottom of the selection unit by a predetermined distance;
the sensors of the sensor unit include a reference sensor !mated in the sensor unit under the reference contact location and configured to be brought into contact with the reference contact location by the selection, a first sensor located in the sensor unit under the first contact location and configured to be brought into contact with the first contact location by the selection, and a second sensor located in the sensor unit under the second contact location and configured to be brought into contact with the second contact location by the selection;
the input module is provided to have predetermined separation distances across which a contact via the selection and a return from the contact location to an original location are made,
in the input module, the separation distances include: a reference interval corresponding to a space along an axis between a predetermined location under the selection unit and the reference sensor of the sensor unit that are spaced apart from each other by a predetermined distance in this axis vertically passing through the reference location; a first interval corresponding to a space along an axis between a predetermined location under the selection unit and the first sensor of the sensor unit that are located to be spaced apart from each other by a predetermined distance in this axis vertically passing through the first side location; and a second interval corresponding, to a space along, the axis between a predetermined location under the selection unit and the second sensor of the sensor unit that are located to be spaced apart from each other by a predetermined distance in this axis vertically passing through the second side location;
the reference interval is configured to be shorter than each of the first interval and the second interval;
in the input module, when the selection of the reference location, the first side location or the second side location is performed, the reference contact location, the first contact location or the second contact location is configured to be moved in a direction of the separation distance, be brought into contact with the sensor of the sensor unit corresponding to the selection, and be returned to its original location;
in the input module, when the selection is performed by a single pressing operation centered on the selection unit, including the reference location, on the basis of the selection via the single finger, a predetermined reference signal is generated in the reference sensor brought into contact with the reference contact location by the selection;
when the selection is performed by a single pressing operation toward a one or remaining side of the selection unit including the first or second side location, a predetermined side signal is generated in the first sensor brought into contact with the first contact location or in the second sensor brought into contact with the second contact location by the selection; and
data execution assigned to the reference signal or the side signal is independently or successively performed.

2. The data execution device of claim 1, wherein:
in the input module, one or more members are provided between the selection unit and the sensor;
the members include a reference,, member provided between the reference location and the reference sensor; and
in the input module, the separation distance under the reference location is configured to be shorter than the separation distance under each of the first side location and the second side location by the reference member.

3. The data execution device of claim 2, wherein:
in the input module, the members include side members; and
the side members include a first member located between the first side location and the first sensor and a second member located between the second side location and the second sensor.

4. The data execution device of claim 3, wherein:
in the input module:
the separation distance under the reference location at which the reference member is located is configured to be shorter than the separation distance under each of the first side location at which the first member of the side members is located and the second side location at which the second member is located.

5. The data execution device of claim 4, wherein:
in the input module:
the reference member and the side members are provided to be identical or different depending on a predetermined criterion; and
the predetermined criterion includes at least one of a size, shape, type and material of the members.

6. The data execution device of claim 3, wherein:
in the input module:
on the basis of the selection via the single finger;
when the selection is performed by a single pressing operation centered on the selection unit including the reference location, a predetermined reference signal is generated in the reference sensor brought into contact with one side of the reference member by the selection; and
when the selection is performed by a single pressing operation toward the one or remaining side of the selection unit including the first or second side location, a predetermined side signal is generated in the first sensor brought into contact with one side of the first member or in the second sensor brought into contact with one side of the second member.

7. The data execution device of claim 3, wherein:
in the input module:
one side of at least one of the reference member and the side members that are brought into contact with the sensors of the sensor unit during the selection is provided in one or more shapes; or
the one side of the at least one is provided to include at least one of a plane portion, a concave portion, a wing portion, a convex portion, a protrusion portion, a variable portion and a protrusion.

8. The data execution device of claim 1, wherein:
with regard to sensor actuation pressures that cause predetermined signals to be generated in the sensors of the sensor unit corresponding to the selection of the selection locations in the input module:
the sensor actuation pressures include a reference sensor actuation pressure that causes the reference sensor of the sensors to operate and generate the reference signal and side sensor actuation pressures that causes the first sensor or the second sensor of the sensors to operate and generate the side signals, and the reference sensor actuation pressure and the side sensor actuation pressures are different.

9. The data execution device of claim 8, wherein;
with regard to the sensor actuation pressures:
the reference sensor actuation pressure related to the reference sensor corresponding to the selection of the center of the selection unit is higher than the side sensor actuation pressure related to the first sensor or the second sensor corresponding to the selection of the one or remaining side of the selection unit; and
the side sensor actuation, pressure related to the first sensor and the side sensor actuation pressure related to the second sensor are different

10. The data execution device of claim 1, wherein:
the reference sensor generating the reference signal and the first and second sensors generating the side signals in the input module are provided to be identical or different depending on a predetermined criterion; and
the predetermined criterion includes at least one of a size, shape, type and material of the sensors.

11. The data execution device of claim 1, wherein:
the input module includes one or more location balancers having a predetermined width and length; and
the location balancers are provided to be located within a space between a bottom of the selection unit and the sensor unit, and are provided between the reference location, spaced apart from the reference location by a predetermined distance in a direction of the side location, and the side locations within the space.

12. The data execution device of claim 11, wherein:
in the input module:
the location balancers are provided to be located at predetermined locations spaced apart from the reference location in a direction of the first side location and a direction of the second side location by a predetermined distance with the space; and
close contact portions are located at one side end of each of the location balancers in a vertical direction or at one and remaining side ends of each of the location balancers in a vertical direction, and the close contact portions are formed to be brought into close contact by the selection.

13. The data execution device of claim 1, wherein:
the selection unit is provided to include at least one of an elastic member and a non-elastic member;
when the selection is performed toward one or remaining side of the selection unit including the elastic member on the basis of the selection via the single finger performed along a single reference line passing through the selection unit in a lateral direction, a predetermined portion of the one side or the other side is inclined or bent downward from the reference line within a predetermined angle; and
when the selection is released, the inclined or bent predetermined portion is returned to its original location.

14. The data execution device of claim 2, wherein:
in the input module,
with regard to a plurality of reference signals or a plurality of side signals generated when the reference signal or the side signal is successively generated based on a difference in a number of selections or a difference in strength of pressing force in the selection of the reference location or the side location:
on the basis of a predetermined time set value:
when a time interval of each signal of the reference signals or the side signals falls within the set time value, the reference signals are processed as a new single reference signal different from each signal of the reference signals or the side signals are processed as a new single side signal different from each signal of the side signals in a predetermined control unit; and
when a time interval of each signal of the reference signals or the side signals exceeds the set time value, the reference signals are processed as respective reference signals successively generated independently or the side signals are processed as side signals successively generated independently in the control unit.

15. A data execution device, in which selection via a selection means is performed in a selection unit and data execution assigned to a signal generated by the selection is performed, wherein:
at least one input module, including a selection unit configured to enable a selection via a finger, which is one of the selection means, to be performed and configured to have a predetermined width and length, and a sensor unit formed under the selection unit and configured to have sensors generating signals in response to the selection, is included;
in the input module, the selection unit includes a single selection unit;
a reference location and side locations corresponding to selection locations at which the selection is performed in the selection unit are provided to be located within a range corresponding to a fingerprint region on the basis of a fingerprint in a distal end portion of a single thumb, the reference location and the side locations are located to be spaced apart from each other by a predetermined distance along a single lateral axis within the selection unit, the reference location is located at one point at a enter of the selection unit, and the side locations include a first side location located on one side of the selection unit and a second side location located on a remaining side of the selection unit;
sensors corresponding to the selection of the reference location and the side location are located in the sensor unit;
the sensors are configured to include a reference sensor located under the reference location, a first sensor located under the first side location, and a second sensor located under the second side location;
a contact unit is provided at a location spaced apart from the sensor unit by a predetermined distance;
contact locations each of which corresponds to the selection of the reference location or the side location and is brought into contact with a corresponding sensor of the sensor unit are located at predetermined locations on a top of the contact unit;
the contact locations include a reference contact location located at a predetermined location between a bottom of the reference sensor and the top of the contact unit and configured to be brought into contact with the reference sensor by the selection, a first contact location located at a predetermined location between a bottom of the first sensor and the top of the contact unit and configured to is brought into contact with the first sensor by the selection, and a second contact location located at a predetermined location between a bottom of the second sensor and the top of the contact unit and configured to be brought into contact with the second sensor by the selection;
the input module is provided to have predetermined separation distances across which a contact via the selection and a return from the contact location to an original location are made,
in the input module, the separation distances include: a reference interval corresponding to a space along a single axis between the reference sensor and the contact unit that are located to be spaced apart from each other by a predetermined distance along this single axis vertically passing through the reference location; a first interval corresponding to a space along a single axis the first sensor the contact unit that are located to be spaced apart from each other by a predetermined distance along this single axis vertically passing through the first side location; and a second interval corresponding to a space along a single axis between the second sensor and the contact unit that are located to be spaced apart from each other by a predetermined distance along this single axis vertically passing through the second side location;
the reference interval is configured to be shorter than each of the first interval and the second interval;
in the input module, when the selection of the reference location, the first side location or the second side location is performed, the reference sensor, the first sensor or the second sensor is moved in a direction of the separation distance, is brought into contact with the contact location of the contact unit corresponding to the selection, and is returned to its original location;
in the input module, when the selection is performed by a single pressing operation centered on the selection unit, including the reference location, on the basis of the selection via the single finger, a predetermined reference signal is generated in the reference sensor brought into contact with the reference contact location by the selection;
when the selection is performed by a single pressing operation toward a one or remaining side of the selection unit including the first or second side location, a predetermined side signal is generated in the first sensor brought into contact with the first contact location or in the second sensor brought into contact with the second contact location by the selection; and
data execution assigned to the reference, signal or the side signal is independently or successively performed.

16. The data execution device of claim 15, wherein:
in the input module, one or more members are provided between the selection unit and the sensor;
the members include a reference member provided between the reference location and the contact unit; and
in the input module, the separation distance under the reference location is configured to be shorter than the separation distance under each of the first side location and the second side location by the reference member.

17. The data execution device of claim 16, wherein;
in the input module, the members include side members; and
the side members include a first member located between the first sensor and the contact unit, and a second member located between the second sensor and the contact unit.

18. The data execution device of claim 17, wherein:
in the input module:
the separation distance under the reference location at which the reference member is located is configured to be shorter than the separation distance under each of the first side location at which the first member of the sided members is located and the second side location at which the second member is located.

19. The data execution device of claim 18, wherein:
in the input module:
the reference member and the side members are provided to be identical or different depending on a predetermined criterion; and
the predetermined criterion includes at least one of a size, shape, type and material the members.

20. The data execution device of claim I, wherein;
the input module includes a plurality of input modules; and
the input modules are located to be spaced apart from each other by a predetermined distance in at least one direction.

21. The data execution device of claim 20, wherein:
the input module includes a first input module and a second input module that are spaced apart by a predetermined distance in a vertical direction;
in a case based on a single reference line located between the first input module and the second input module in a lateral direction,
when the selection via a single finger is performed by a single pressing operation toward a center of the selection unit of the first input module and a center of the selection unit of the second input module on the basis of the reference line, the reference location of the selection unit of the first input module and the reference location of the selection unit of the second input module are selected together by the finger;
generation of a single reference signal in the reference sensor brought into contact with the reference contact location of the first input module and generation of another single reference signal in the reference sensor brought into contact with the reference contact location of the second input module are performed together by the selection; and
in a predetermined control unit, the single reference signal and the other single reference signal are processed as a dim' I reference signal, which is a new single reference signal, on the basis of predetermined set values of a plurality of signals.

22. The data execution device of claim 20, wherein:
the input module includes a first input module and a second input module that are spaced apart by a predetermined distance in a vertical direction;
in a case based on a single reference line located between the first input module and the second input module in a lateral direction,
the selection via the single finger is performed by a single pressing operation for one side of the selection unit of the first input module and a remaining side of the selection unit of the second input module, or a remaining side of the selection unit of the first input module and a remaining side of the selection land of the second input module on the basis of the reference line, the first side location of the selection unit of the first input module and the first side location of the selection unit of the second input module, or the second side location of the selection unit of the first input module and the second side location of the selection unit of the second input module are selected together by the finger;
generation of a single one side signal in the first sensor brought into contact with the first contact location of the first input module and generation of another single one side signal in the first sensor brought into contact with the first contact location of the second input module, or generation of a single other side signal in the second sensor brought into contact with the second contact location of the first input module and generation of another single other side signal in the second sensor brought into contact with the second contact location of the second input module are performed together by the selection; and, the single one side signal and the single one side signal, or the single other side signal and the single other side signal are processed as a third side signal, which is a new, single side signal, on the basis of predetermined set values of a plurality of signals in a predetermined control unit.

23. The data execution device of claim 20, wherein:
the input module includes a first input module and a second input module that are spaced apart predetermined distance lateral direction;
in a case based on a single reference line located between the first input module and the second input module in a vertical direction:
when the selection via the single finger is performed by a single pressing operation for a remaining side of the selection unit of the first input module and one side of the selection unit of the second input module, or one side of the selection unit of the first input module and a remaining side of the selection unit affix second input module on the basis of the reference line, the second side location of the selection unit of the first input module and the first side location of the selection unit of the second input module, or the first side location of the selection unit of the first input module and the second side location of the selection unit of the second input module are selected together by the finger;
generation of a single other side signal in the second sensor brought into contact with the second contact location of the first input module and generation of a single one side signal in the first sensor brought into contact with the first contact location of the second input module, or generation of a single one side signal in the first sensor brought into contact with the first contact location of the first input module and generation of a single other side signal in the second sensor brought into contact with the second contact location of the second input module are performed together by the selection; and
the single other side signal and the single one side signal, or the single one side signal and the single other side signal are processed as a third side signal, which is a new single side signal, on the basis of predetermined set values of a plurality of signals in a predetermined control unit.

24. The data execution device of claim 23, wherein:
in the input module:
the separation distance under the second side location of the first input module and the separation distance under the first side location of the second input module are configured to be different.

25. The data execution device of claim 1, wherein:
the input module or the selection unit of the input module is provided according to a predetermined criterion;
the predetermined criterion includes at least one of size, shape, member and material; and
the shape includes at least one of a plane portion, a concave portion, a protrusion, a line, a groove, a protrusion portion and an asymmetric shape.

26. The data execution device of claim 1, wherein:
the selection unit includes a plurality of selection units; and
one and another selection units of the selection units that are spaced apart from each other by a predetermined distance in at least one direction are located to be connected by a predetermined connection frame.

27. The data execution device of claim 1, wherein:
the input module is detachably provided on a body of an execution device that performs the data execution.

28. The data execution device of claim 27, wherein:
terminals configured to transfer a predetermined signal of the input module or the execution device or a transfer signal of data assigned to the signal are provided at predetermined locations of the input module and the body.

29. The data execution device of claim 27, wherein:
a fastening means configured to fasten the input module and the body to each other are provided at one or more predetermined locations of the input module and the body; and
the fastening means includes one or more fastening members of a protrusion, groove, a slot, a guide, a latch, a hook, a holder, a band and a Velcro fastener.
